(19) United States
(12) Patent Application Publication
(10) Pub. No.: US 2026/0303125 A1
(43) Pub. Date: Oct. 1, 2026

(54) Encoding Method, Decoding Method, and Related Product

(71) Applicant: HUAWEI TECHNOLOGIES CO., LTD., Shenzhen (CN)

(72) Inventors: Kangjian Qin, Hangzhou (CN); Huazi Zhang, Hangzhou (CN); Xianbin Wang, Hangzhou (CN); Ke Liu, Hangzhou (CN); Jiajie Tong, Hangzhou (CN); Jun Wang, Hangzhou (CN)

(73) Assignee: HUAWEI TECHNOLOGIES CO., LTD., Shenzhen (CN)

(21) Appl. No.: 19/689,109

(22) Filed: May 27, 2026

Related U.S. Application Data
(63) Continuation of application No. PCT/CN2024/134677, filed on Nov. 26, 2024.

(30) Foreign Application Priority Data
Nov. 28, 2023 (CN) 202311613726.8

(51) Int. Cl. H03M 13/27; H03M 13/09

(52) U.S. Cl. CPC H03M 13/27; H03M 13/09

(57) ABSTRACT

A method may be applied to low-power scenarios and includes: performing cyclic redundancy check (CRC) encoding on K1 information bits, to obtain a first bit sequence, where the first bit sequence includes L CRC bits, K1 is a positive integer, and L is a positive integer less than 24; and performing interleaving on the first bit sequence by using a first distributed CRC interleaver, where the first distributed CRC interleaver includes (K2+L) elements, and values of a (K2+L−S)^{th} element to a (K2+L)^{th} element in the first distributed CRC interleaver are sequentially (K2+L−1−S) to (K2+L−1); or the first distributed CRC interleaver includes a total of (K2+L) natural numbers ranging from 0 to (K2+L−1), and P in the first distributed CRC interleaver is before Q.

### CROSS-REFERENCE TO RELATED APPLICATIONS

This is a continuation of International Patent Application No. PCT/CN2024/134677 filed on Nov. 26, 2024, which claims priority to Chinese Patent Application No. 202311613726.8 filed on Nov. 28, 2023, which are hereby incorporated by reference in their entireties.

### TECHNICAL FIELD

This disclosure relates to the field of communication technologies, and in particular, to an encoding method, a decoding method, and a related product.

### BACKGROUND

In a wireless transmission process, channel coding is typically used to encode and decode data, so as to improve information transmission reliability and reduce an error probability in the transmission process.

In New Radio (NR) systems, one type of channel coding used is as follows: cyclic redundancy check (CRC) encoding is first performed on K bits (payload bits) to be transmitted over downlink control channels, to obtain 24 cyclic redundancy check bits. The 24 cyclic redundancy check bits are concatenated to the end of the K bits, to obtain a message sequence concatenated with the 24 cyclic redundancy check bits. Interleaving is performed on the message sequence by using an interleaver, to obtain an interleaved sequence. Finally, polar encoding is performed on the interleaved sequence. In this solution, a size K of payloads (the payload bits) is less than or equal to 140, and a maximum length of the payloads concatenated with the 24 cyclic redundancy check bits is 164. Therefore, a length of the interleaver is 164.

However, such a channel coding scheme has problems of high decoding power consumption and high resource overheads in low-power scenarios, 1st-stage downlink control information (DCI) scenarios, and other scenarios.

### SUMMARY

Embodiments of this disclosure disclose an encoding method, a decoding method, and a related product, to reduce decoding power consumption and resource overheads.

According to a first aspect, an embodiment of this disclosure provides an encoding method. The method includes: performing CRC encoding on K1 information bits, to obtain a first bit sequence, where the first bit sequence includes the K1 information bits and L CRC bits, K1 is a positive integer, and L is a positive integer less than 24; and performing interleaving on the first bit sequence by using a first distributed CRC interleaver, to obtain a second bit sequence, where the first distributed CRC interleaver includes (K2+L) elements, values of a (K2+L−S)^{th} element to a (K2+L)^{th} element in the first distributed CRC interleaver are sequentially (K2+L−1−S) to (K2+L−1), S is an integer greater than or equal to 0 and less than or equal to L, and K2 is an integer greater than or equal to K1; or the first distributed CRC interleaver includes a total of (K2+L) natural numbers ranging from 0 to (K2+L−1), P in the first distributed CRC interleaver is before Q, both P and Q are integers greater than or equal to K2, and P is greater than Q. That the values of the (K2+L−S)^{th} element to the (K2+L)^{th} element in the first distributed CRC interleaver are sequentially (K2+L−1−S) to (K2+L−1) may be replaced with that the first distributed CRC interleaver includes L natural numbers that are arranged in ascending order and are greater than or equal to K2.

In this embodiment of this disclosure, cyclic redundancy check CRC encoding is performed on the K1 information bits, to obtain the first bit sequence. A quantity of CRC check bits is less than 24. Interleaving is performed on the first bit sequence by using the first distributed CRC interleaver. The first distributed CRC interleaver supports distributed CRC (DCRC) encoding with a shorter payload, and a receiving side performs decoding by using a deinterleaver corresponding to the first distributed CRC interleaver, so that decoding power consumption and resource overheads can be reduced.

In a possible implementation, L is equal to 6, 11, or 16.

In a possible implementation, K2 is equal to 32, 40, 48, 54, 64, 70, or 100.

In a possible implementation, the first distributed CRC interleaver is obtained by sequentially arranging L element sequences, any two of the L element sequences are a first element sequence and a second element sequence, an element included in the first element sequence is obtained based on a position of an information bit associated with a first check column, and an element included in the second element sequence is obtained based on a position of an information bit associated with a second check column, the first check column and the second check column are any two columns in a check matrix obtained based on an L-length CRC generator polynomial, and when a largest element that is in the first element sequence and that represents the position of the information bit associated with the first check column is greater than a largest element that is in the second element sequence and that represents the position of the information bit associated with the second check column, the first element sequence in the first distributed CRC interleaver is arranged after the second element sequence.

In this implementation, when the largest element that is in the first element sequence and that represents the position of the information bit associated with the first check column is greater than the largest element that is in the second element sequence and that represents the position of the information bit associated with the second check column, the first element sequence in the first distributed CRC interleaver is arranged after the second element sequence, so that the receiving side can detect a CRC check failure earlier during decoding, thereby reducing decoding power consumption.

In a possible implementation, the performing cyclic redundancy check CRC encoding on the K1 information bits, to obtain the first bit sequence includes: performing CRC encoding on the K1 information bits based on the CRC generator polynomial, to obtain the first bit sequence, where Lis equal to 6, K2 is equal to 70, the CRC generator polynomial is D\hat{ }6+D\hat{ }5+1, and values of the elements in the first distributed CRC interleaver are sequentially as follows: 0, 2, 3, 4, 5, 6, 7, 13, 18, 19, 23, 25, 28, 29, 30, 31, 33, 37, 38, 39, 42, 45, 47, 48, 50, 51, 52, 54, 55, 58, 59, 61, 63, 65, 66, 67, 68, 69, 70, 1, 8, 14, 20, 24, 26, 32, 34, 40, 43, 46, 49, 53, 56, 60, 62, 64, 71, 9, 15, 21, 27, 35, 41, 44, 57, 72, 10, 16, 22, 36, 73, 11, 17, 74, 12, and 75.

In a possible implementation, the performing cyclic redundancy check CRC encoding on the K1 information bits, to obtain the first bit sequence includes: performing CRC encoding on the K1 information bits based on the CRC generator polynomial, to obtain the first bit sequence, where L is equal to 6, K2 is equal to 70, the CRC generator polynomial is D\hat{ }6+D\hat{ }5+D\hat{ }4+D\hat{ }3+1, and values of the elements in the first distributed CRC interleaver are sequentially as follows: 1, 4, 5, 6, 9, 10, 16, 19, 20, 21, 24, 25, 31, 34, 35, 36, 39, 40, 46, 49, 50, 51, 54, 55, 61, 64, 65, 66, 69, 70, 2, 7, 11, 17, 22, 26, 32, 37, 41, 47, 52, 56, 62, 67, 71, 3, 8, 12, 18, 23, 27, 33, 38, 42, 48, 53, 57, 63, 68, 72, 13, 28, 43, 58, 73, 14, 29, 44, 59, 74, 0, 15, 30, 45, 60, and 75.

In a possible implementation, the performing cyclic redundancy check CRC encoding on the K1 information bits, to obtain the first bit sequence includes: performing CRC encoding on the K1 information bits based on the CRC generator polynomial, to obtain the first bit sequence, where L is equal to 6, K2 is equal to 70, the CRC generator polynomial is D\hat{ }6+D\hat{ }4+D\hat{ }3+D+1, and values of the elements in the first distributed CRC interleaver are sequentially as follows: 0, 1, 2, 3, 4, 5, 7, 13, 14, 15, 20, 23, 27, 28, 30, 31, 34, 36, 37, 39, 41, 42, 43, 45, 46, 47, 48, 51, 52, 56, 58, 60, 63, 64, 65, 66, 67, 68, 70, 6, 8, 16, 21, 24, 29, 32, 35, 38, 40, 44, 49, 53, 57, 59, 61, 69, 71, 9, 17, 22, 25, 33, 50, 54, 62, 72, 10, 18, 26, 55, 73, 11, 19, 74, 12, and 75.

In a possible implementation, the performing cyclic redundancy check CRC encoding on the K1 information bits, to obtain the first bit sequence includes: performing CRC encoding on the K1 information bits based on the CRC generator polynomial, to obtain the first bit sequence, where L is equal to 6, K2 is equal to 70, the CRC generator polynomial is D\hat{ }6+D\hat{ }3+D\hat{ }2+D+1, and values of the elements in the first distributed CRC interleaver are sequentially as follows: 1, 2, 5, 6, 7, 10, 16, 17, 20, 21, 22, 25, 31, 32, 35, 36, 37, 40, 46, 47, 50, 51, 52, 55, 61, 62, 65, 66, 67, 70, 3, 8, 11, 18, 23, 26, 33, 38, 41, 48, 53, 56, 63, 68, 71, 4, 9, 12, 19, 24, 27, 34, 39, 42, 49, 54, 57, 64, 69, 72, 13, 28, 43, 58, 73, 14, 29, 44, 59, 74, 0, 15, 30, 45, 60, and 75.

In a possible implementation, the performing cyclic redundancy check CRC encoding on the K1 information bits, to obtain the first bit sequence includes: performing CRC encoding on the K1 information bits based on the CRC generator polynomial, to obtain the first bit sequence, where L is equal to 6, K2 is equal to 70, the CRC generator polynomial is D\hat{ }6+D\hat{ }5+D\hat{ }2+1, and values of the elements in the first distributed CRC interleaver are sequentially as follows: 0, 1, 2, 4, 5, 6, 7, 13, 15, 17, 18, 21, 22, 23, 25, 26, 27, 28, 34, 36, 38, 39, 42, 43, 44, 46, 47, 48, 49, 55, 57, 59, 60, 63, 64, 65, 67, 68, 69, 70, 3, 8, 14, 16, 19, 24, 29, 35, 37, 40, 45, 50, 56, 58, 61, 66, 71, 9, 20, 30, 41, 51, 62, 72, 10, 31, 52, 73, 11, 32, 53, 74, 12, 33, 54, and 75.

In a possible implementation, the performing cyclic redundancy check CRC encoding on the K1 information bits, to obtain the first bit sequence includes: performing CRC encoding on the K1 information bits based on the CRC generator polynomial, to obtain the first bit sequence, where L is equal to 6, K2 is equal to 70, the CRC generator polynomial is D\hat{ }6+D\hat{ }5+D\hat{ }4+D\hat{ }2+1, and values of the elements in the first distributed CRC interleaver are sequentially as follows: 0, 1, 4, 6, 7, 13, 15, 18, 21, 22, 25, 27, 28, 34, 36, 39, 42, 43, 46, 48, 49, 55, 57, 60, 63, 64, 67, 69, 70, 2, 5, 8, 14, 16, 19, 23, 26, 29, 35, 37, 40, 44, 47, 50, 56, 58, 61, 65, 68, 71, 3, 9, 17, 20, 24, 30, 38, 41, 45, 51, 59, 62, 66, 72, 10, 31, 52, 73, 11, 32, 53, 74, 12, 33, 54, and 75.

In a possible implementation, the performing cyclic redundancy check CRC encoding on the K1 information bits, to obtain the first bit sequence includes: performing CRC encoding on the K1 information bits based on the CRC generator polynomial, to obtain the first bit sequence, where L is equal to 6, K2 is equal to 70, the CRC generator polynomial is D\hat{ }6+D\hat{ }3+D\hat{ }2+1, and values of the elements in the first distributed CRC interleaver are sequentially as follows: 0, 4, 5, 8, 14, 16, 17, 18, 20, 21, 23, 25, 28, 29, 30, 31, 35, 36, 39, 45, 47, 48, 49, 51, 52, 54, 56, 59, 60, 61, 62, 66, 67, 70, 1, 6, 9, 15, 19, 22, 24, 26, 32, 37, 40, 46, 50, 53, 55, 57, 63, 68, 71, 2, 7, 10, 27, 33, 38, 41, 58, 64, 69, 72, 3, 11, 34, 42, 65, 73, 12, 43, 74, 13, 44, and 75.

In a possible implementation, the performing cyclic redundancy check CRC encoding on the K1 information bits, to obtain the first bit sequence includes: performing CRC encoding on the K1 information bits based on the CRC generator polynomial, to obtain the first bit sequence, where L is equal to 6, K2 is equal to 70, the CRC generator polynomial is D\hat{ }6+D\hat{ }5+D\hat{ }3+D\hat{ }2+1, and values of the elements in the first distributed CRC interleaver are sequentially as follows: 0, 5, 6, 7, 13, 15, 16, 17, 18, 19, 20, 23, 25, 27, 31, 32, 35, 36, 37, 38, 40, 41, 42, 44, 46, 47, 49, 52, 53, 55, 56, 60, 63, 68, 69, 70, 1, 8, 14, 21, 24, 26, 28, 33, 39, 43, 45, 48, 50, 54, 57, 61, 64, 71, 2, 9, 22, 29, 34, 51, 58, 62, 65, 72, 3, 10, 30, 59, 66, 73, 4, 11, 67, 74, 12, and 75.

In a possible implementation, the performing cyclic redundancy check CRC encoding on the K1 information bits, to obtain the first bit sequence includes: performing CRC encoding on the K1 information bits based on the CRC generator polynomial, to obtain the first bit sequence, where L is equal to 6, K2 is equal to 70, the CRC generator polynomial is D\hat{ }6+D\hat{ }5+D\hat{ }4+D\hat{ }3+D\hat{ }2+1, and values of the elements in the first distributed CRC interleaver are sequentially as follows: 0, 2, 5, 9, 10, 16, 18, 19, 21, 22, 23, 26, 27, 28, 29, 30, 32, 35, 39, 40, 46, 48, 49, 51, 52, 53, 56, 57, 58, 59, 60, 62, 65, 69, 70, 1, 3, 6, 11, 17, 20, 24, 31, 33, 36, 41, 47, 50, 54, 61, 63, 66, 71, 4, 7, 12, 25, 34, 37, 42, 55, 64, 67, 72, 8, 13, 38, 43, 68, 73, 14, 44, 74, 15, 45, and 75.

In a possible implementation, the performing cyclic redundancy check CRC encoding on the K1 information bits, to obtain the first bit sequence includes: performing CRC encoding on the K1 information bits based on the CRC generator polynomial, to obtain the first bit sequence, where L is equal to 6, K2 is equal to 70, the CRC generator polynomial is D\hat{ }6+D\hat{ }5+D\hat{ }4+D\hat{ }3+D+1, and values of the elements in the first distributed CRC interleaver are sequentially as follows: 1, 2, 4, 7, 8, 14, 15, 16, 19, 23, 25, 27, 28, 29, 30, 32, 33, 35, 38, 39, 45, 46, 47, 50, 54, 56, 58, 59, 60, 61, 63, 64, 66, 69, 70, 0, 3, 5, 9, 17, 20, 24, 26, 31, 34, 36, 40, 48, 51, 55, 57, 62, 65, 67, 71, 6, 10, 18, 21, 37, 41, 49, 52, 68, 72, 11, 22, 42, 53, 73, 12, 43, 74, 13, 44, and 75.

In a possible implementation, the performing cyclic redundancy check CRC encoding on the K1 information bits, to obtain the first bit sequence includes: performing CRC encoding on the K1 information bits based on the CRC generator polynomial, to obtain the first bit sequence, where L is equal to 6, K2 is equal to 70, the CRC generator polynomial is D\hat{ }6+D\hat{ }4+D\hat{ }2+D+1, and values of the elements in the first distributed CRC interleaver are sequentially as follows: 2, 5, 7, 13, 14, 16, 19, 20, 23, 26, 28, 34, 35, 37, 40, 41, 44, 47, 49, 55, 56, 58, 61, 62, 65, 68, 70, 0, 3, 6, 8, 15, 17, 21, 24, 27, 29, 36, 38, 42, 45, 48, 50, 57, 59, 63, 66, 69, 71, 1, 4, 9, 18, 22, 25, 30, 39, 43, 46, 51, 60, 64, 67, 72, 10, 31, 52, 73, 11, 32, 53, 74, 12, 33, 54, and 75.

In a possible implementation, the performing cyclic redundancy check CRC encoding on the K1 information bits, to obtain the first bit sequence includes: performing CRC encoding on the K1 information bits based on the CRC generator polynomial, to obtain the first bit sequence, where L is equal to 11, K2 is equal to 70, the CRC generator polynomial is D\hat{ }11+D\hat{ }10+D\hat{ }9+D\hat{ }5+1, and values of the elements in the first distributed CRC interleaver are sequentially as follows: 0, 1, 2, 3, 4, 6, 7, 10, 13, 15, 19, 21, 22, 23, 24, 25, 27, 30, 33, 34, 35, 37, 41, 44, 46, 47, 48, 49, 50, 55, 57, 58, 59, 60, 61, 62, 63, 66, 67, 69, 70, 5, 8, 11, 14, 16, 20, 26, 28, 31, 36, 38, 42, 45, 51, 56, 64, 68, 71, 9, 12, 17, 29, 32, 39, 43, 52, 65, 72, 18, 40, 53, 73, 54, 74, 75, 76, 77, 78, 79, and 80.

In a possible implementation, the performing cyclic redundancy check CRC encoding on the K1 information bits, to obtain the first bit sequence includes: performing CRC encoding on the K1 information bits based on the CRC generator polynomial, to obtain the first bit sequence, where L is equal to 11, K2 is equal to 70, the CRC generator polynomial is D\hat{ }11+D\hat{ }7+D\hat{ }6+D\hat{ }2+1, and values of the elements in the first distributed CRC interleaver are sequentially as follows: 1, 5, 11, 13, 15, 16, 19, 20, 23, 24, 29, 30, 31, 32, 33, 35, 37, 39, 41, 43, 47, 52, 53, 54, 55, 56, 57, 58, 59, 60, 61, 62, 65, 66, 70, 2, 6, 12, 14, 17, 21, 25, 34, 36, 38, 40, 42, 44, 48, 63, 67, 71, 3, 7, 18, 22, 26, 45, 49, 64, 68, 72, 0, 4, 8, 27, 46, 50, 69, 73, 9, 28, 51, 74, 10, 75, 76, 77, 78, 79, and 80.

In a possible implementation, the performing cyclic redundancy check CRC encoding on the K1 information bits, to obtain the first bit sequence includes: performing CRC encoding on the K1 information bits based on the CRC generator polynomial, to obtain the first bit sequence, where L is equal to 11, K2 is equal to 70, the CRC generator polynomial is D\hat{ }11+D\hat{ }10+D\hat{ }9+D\hat{ }6+D\hat{ }4+D\hat{ }2+1, and values of the elements in the first distributed CRC interleaver are sequentially as follows: 0, 1, 5, 6, 9, 10, 12, 13, 14, 16, 19, 21, 22, 23, 24, 25, 26, 29, 34, 36, 37, 38, 41, 43, 47, 49, 50, 51, 52, 54, 61, 63, 64, 65, 66, 67, 69, 70, 2, 7, 11, 15, 17, 20, 27, 30, 35, 39, 42, 44, 48, 53, 55, 62, 68, 71, 3, 8, 18, 28, 31, 40, 45, 56, 72, 4, 32, 46, 57, 73, 33, 58, 74, 59, 75, 60, 76, 77, 78, 79, and 80.

In a possible implementation, the performing cyclic redundancy check CRC encoding on the K1 information bits, to obtain the first bit sequence includes: performing CRC encoding on the K1 information bits based on the CRC generator polynomial, to obtain the first bit sequence, where L is equal to 11, K2 is equal to 70, the CRC generator polynomial is D\hat{ }11+D\hat{ }10+D\hat{ }9+D\hat{ }7+D\hat{ }5+D+1, and values of the elements in the first distributed CRC interleaver are sequentially as follows: 0, 5, 7, 8, 11, 12, 16, 18, 19, 21, 22, 24, 25, 27, 30, 34, 38, 39, 46, 50, 53, 54, 55, 58, 59, 63, 64, 67, 69, 70, 1, 6, 9, 13, 17, 20, 23, 26, 28, 31, 35, 40, 47, 51, 56, 60, 65, 68, 71, 2, 10, 14, 29, 32, 36, 41, 48, 52, 57, 61, 66, 72, 3, 15, 33, 37, 42, 49, 62, 73, 4, 43, 74, 44, 75, 45, 76, 77, 78, 79, and 80.

In a possible implementation, the performing cyclic redundancy check CRC encoding on the K1 information bits, to obtain the first bit sequence includes: performing CRC encoding on the K1 information bits based on the CRC generator polynomial, to obtain the first bit sequence, where L is equal to 11, K2 is equal to 70, the CRC generator polynomial is D\hat{ }11+D\hat{ }9+D\hat{ }8+D\hat{ }6+D\hat{ }5+D+1, and values of the elements in the first distributed CRC interleaver are sequentially as follows: 0, 10, 15, 18, 20, 21, 22, 23, 24, 27, 29, 31, 32, 35, 36, 38, 41, 42, 44, 46, 47, 49, 53, 54, 55, 58, 59, 63, 64, 65, 66, 67, 68, 70, 1, 11, 16, 19, 25, 28, 30, 33, 37, 39, 43, 45, 48, 50, 56, 60, 69, 71, 2, 12, 17, 26, 34, 40, 51, 57, 61, 72, 3, 13, 52, 62, 73, 4, 14, 74, 5, 75, 6, 76, 7, 77, 8, 78, 9, 79, and 80.

In a possible implementation, the performing cyclic redundancy check CRC encoding on the K1 information bits, to obtain the first bit sequence includes: performing CRC encoding on the K1 information bits based on the CRC generator polynomial, to obtain the first bit sequence, where L is equal to 11, K2 is equal to 70, the CRC generator polynomial is D\hat{ }11+D\hat{ }10+D\hat{ }9+D\hat{ }8+D\hat{ }7+D\hat{ }5+D\hat{ }4+D+1, and values of the elements in the first distributed CRC interleaver are sequentially as follows: 1, 2, 4, 5, 8, 9, 11, 13, 17, 18, 20, 24, 27, 28, 30, 32, 33, 36, 39, 40, 41, 42, 43, 44, 47, 49, 52, 53, 54, 55, 61, 62, 63, 65, 69, 70, 3, 6, 10, 12, 14, 19, 21, 25, 29, 31, 34, 37, 45, 48, 50, 56, 64, 66, 71, 7, 15, 22, 26, 35, 38, 46, 51, 57, 67, 72, 0, 16, 23, 58, 68, 73, 59, 74, 60, 75, 76, 77, 78, 79, and 80.

In a possible implementation, the performing cyclic redundancy check CRC encoding on the K1 information bits, to obtain the first bit sequence includes: performing CRC encoding on the K1 information bits based on the CRC generator polynomial, to obtain the first bit sequence, where Lis equal to 11, K2 is equal to 70, the CRC generator polynomial is D\hat{ }11+D\hat{ }10+D\hat{ }3+D+1, and values of the elements in the first distributed CRC interleaver are sequentially as follows: 2, 3, 4, 5, 9, 16, 17, 18, 19, 20, 22, 25, 28, 29, 30, 31, 32, 33, 38, 39, 40, 42, 44, 47, 50, 52, 53, 56, 58, 60, 61, 63, 64, 65, 66, 67, 68, 69, 70, 0, 6, 10, 21, 23, 26, 34, 41, 43, 45, 48, 51, 54, 57, 59, 62, 71, 1, 7, 11, 24, 27, 35, 46, 49, 55, 72, 8, 12, 36, 73, 13, 37, 74, 14, 75, 15, 76, 77, 78, 79, and 80.

In a possible implementation, the performing cyclic redundancy check CRC encoding on the K1 information bits, to obtain the first bit sequence includes: performing CRC encoding on the K1 information bits based on the CRC generator polynomial, to obtain the first bit sequence, where Lis equal to 11, K2 is equal to 70, the CRC generator polynomial is D\hat{ }11+D\hat{ }5+D\hat{ }3+D+1, and values of the elements in the first distributed CRC interleaver are sequentially as follows: 2, 5, 13, 14, 15, 16, 20, 23, 27, 30, 32, 34, 35, 36, 37, 38, 39, 40, 43, 47, 48, 52, 54, 58, 59, 60, 62, 64, 70, 0, 3, 6, 17, 21, 24, 28, 31, 33, 41, 44, 49, 53, 55, 61, 63, 65, 71, 1, 4, 7, 18, 22, 25, 29, 42, 45, 50, 56, 66, 72, 8, 19, 26, 46, 51, 57, 67, 73, 9, 68, 74, 10, 69, 75, 11, 76, 12, 77, 78, 79, and 80.

In a possible implementation, the performing cyclic redundancy check CRC encoding on the K1 information bits, to obtain the first bit sequence includes: performing CRC encoding on the K1 information bits based on the CRC generator polynomial, to obtain the first bit sequence, where L is equal to 11, K2 is equal to 70, the CRC generator polynomial is D\hat{ }11+D\hat{ }10+D\hat{ }9+D\hat{ }8+D\hat{ }6+D\hat{ }5+D\hat{ }3+D+1, and values of the elements in the first distributed CRC interleaver are sequentially as follows: 0, 1, 3, 4, 5, 8, 9, 10, 13, 22, 24, 28, 33, 34, 39, 41, 46, 47, 49, 53, 54, 56, 57, 60, 61, 62, 63, 64, 66, 69, 70, 2, 6, 11, 14, 23, 25, 29, 35, 40, 42, 48, 50, 55, 58, 65, 67, 71, 7, 12, 15, 26, 30, 36, 43, 51, 59, 68, 72, 16, 27, 31, 37, 44, 52, 73, 17, 32, 38, 45, 74, 18, 75, 19, 76, 20, 77, 21, 78, 79, and 80.

In a possible implementation, the performing cyclic redundancy check CRC encoding on the K1 information bits, to obtain the first bit sequence includes: performing CRC encoding on the K1 information bits based on the CRC generator polynomial, to obtain the first bit sequence, where L is equal to 11, K2 is equal to 70, the CRC generator polynomial is D\hat{ }11+D\hat{ }10+D\hat{ }8+D\hat{ }7+D\hat{ }6+D\hat{ }5+D\hat{ }3+D+1, and values of the elements in the first distributed CRC interleaver are sequentially as follows: 0, 3, 5, 6, 7, 8, 11, 13, 15, 17, 19, 21, 22, 26, 27, 30, 31, 32, 33, 35, 36, 41, 42, 43, 47, 49, 53, 61, 62, 65, 68, 69, 70, 1, 4, 9, 12, 14, 16, 18, 20, 23, 28, 34, 37, 44, 48, 50, 54, 63, 66, 71, 2, 10, 24, 29, 38, 45, 51, 55, 64, 67, 72, 25, 39, 46, 52, 56, 73, 40, 57, 74, 58, 75, 59, 76, 60, 77, 78, 79, and 80.

In a possible implementation, the performing cyclic redundancy check CRC encoding on the K1 information bits, to obtain the first bit sequence includes: performing CRC encoding on the K1 information bits based on the CRC generator polynomial, to obtain the first bit sequence, where L is equal to 11, K2 is equal to 70, the CRC generator polynomial is D\hat{ }11+D\hat{ }9+D\hat{ }7+D\hat{ }6+D\hat{ }5+D\hat{ }4+D\hat{ }3+D+1, and values of the elements in the first distributed CRC interleaver are sequentially as follows: 1, 4, 6, 9, 12, 14, 15, 16, 23, 28, 30, 34, 35, 37, 38, 39, 41, 42, 43, 45, 46, 47, 48, 51, 52, 53, 56, 60, 61, 63, 65, 68, 70, 2, 5, 7, 10, 13, 17, 24, 29, 31, 36, 40, 44, 49, 54, 57, 62, 64, 66, 69, 71, 0, 3, 8, 11, 18, 25, 32, 50, 55, 58, 67, 72, 19, 26, 33, 59, 73, 20, 27, 74, 21, 75, 22, 76, 77, 78, 79, and 80.

In a possible implementation, the performing cyclic redundancy check CRC encoding on the K1 information bits, to obtain the first bit sequence includes: performing CRC encoding on the K1 information bits based on the CRC generator polynomial, to obtain the first bit sequence, where L is equal to 11, K2 is equal to 70, the CRC generator polynomial is D\hat{ }11+D\hat{ }10+D\hat{ }9+D\hat{ }7+D\hat{ }6+D\hat{ }3+D\hat{ }2+D+1, and values of the elements in the first distributed CRC interleaver are sequentially as follows: 2, 3, 6, 8, 9, 11, 12, 13, 14, 21, 24, 26, 27, 28, 29, 30, 31, 32, 34, 36, 37, 38, 39, 40, 41, 47, 48, 49, 53, 54, 57, 61, 65, 67, 69, 70, 0, 4, 7, 10, 15, 22, 25, 33, 35, 42, 50, 55, 58, 62, 66, 68, 71, 1, 5, 16, 23, 43, 51, 56, 59, 63, 72, 17, 44, 52, 60, 64, 73, 18, 45, 74, 19, 46, 75, 20, 76, 77, 78, 79, and 80.

In a possible implementation, the performing cyclic redundancy check CRC encoding on the K1 information bits, to obtain the first bit sequence includes: performing CRC encoding on the K1 information bits based on the CRC generator polynomial, to obtain the first bit sequence, where L is equal to 11, K2 is equal to 70, the CRC generator polynomial is D\hat{ }11+D\hat{ }8+D\hat{ }6+D\hat{ }5+D\hat{ }4+D\hat{ }3+D\hat{ }2+D+1, and values of the elements in the first distributed CRC interleaver are sequentially as follows: 2, 3, 4, 5, 6, 7, 12, 14, 16, 20, 22, 23, 26, 31, 34, 37, 39, 40, 41, 44, 46, 49, 51, 52, 53, 54, 58, 62, 63, 65, 67, 70, 0, 8, 13, 15, 17, 21, 24, 27, 32, 35, 38, 42, 45, 47, 50, 55, 59, 64, 66, 68, 71, 1, 9, 18, 25, 28, 33, 36, 43, 48, 56, 60, 69, 72, 10, 19, 29, 57, 61, 73, 11, 30, 74, 75, 76, 77, 78, 79, and 80.

In a possible implementation, the performing cyclic redundancy check CRC encoding on the K1 information bits, to obtain the first bit sequence includes: performing CRC encoding on the K1 information bits based on the CRC generator polynomial, to obtain the first bit sequence, where L is equal to 16, K2 is equal to 100, the CRC generator polynomial is D\hat{ }16+D\hat{ }12+D\hat{ }5+1, and values of the elements in the first distributed CRC interleaver are sequentially as follows: 2, 4, 5, 12, 14, 16, 18, 19, 20, 23, 25, 26, 28, 30, 33, 34, 35, 36, 37, 42, 44, 45, 48, 49, 51, 52, 58, 65, 67, 68, 72, 73, 74, 78, 80, 81, 88, 89, 92, 96, 100, 3, 6, 13, 15, 17, 21, 24, 27, 29, 31, 38, 43, 46, 50, 53, 59, 66, 69, 75, 79, 82, 90, 93, 97, 101, 7, 22, 32, 39, 47, 54, 60, 70, 76, 83, 91, 94, 98, 102, 8, 40, 55, 61, 71, 77, 84, 95, 99, 103, 0, 9, 41, 56, 62, 85, 104, 1, 10, 57, 63, 86, 105, 11, 64, 87, 106, 107, 108, 109, 110, 111, 112, 113, 114, and 115.

In a possible implementation, the performing cyclic redundancy check CRC encoding on the K1 information bits, to obtain the first bit sequence includes: performing CRC encoding on the K1 information bits based on the CRC generator polynomial, to obtain the first bit sequence, where L is equal to 6, K2 is equal to 70, the CRC generator polynomial is D\hat{ }6+D\hat{ }5+1, and values of the elements in the first distributed CRC interleaver are sequentially as follows: 0, 1, 2, 8, 13, 14, 18, 20, 23, 24, 25, 26, 28, 32, 33, 34, 37, 40, 42, 43, 45, 46, 47, 49, 50, 53, 54, 56, 58, 60, 61, 62, 63, 64, 65, 71, 3, 9, 15, 19, 21, 27, 29, 35, 38, 41, 44, 48, 51, 55, 57, 59, 66, 72, 4, 10, 16, 22, 30, 36, 39, 52, 67, 73, 5, 11, 17, 31, 68, 74, 6, 7, 69, 70, 12, and 75.

In a possible implementation, the performing cyclic redundancy check CRC encoding on the K1 information bits, to obtain the first bit sequence includes: performing CRC encoding on the K1 information bits based on the CRC generator polynomial, to obtain the first bit sequence, where L is equal to 11, K2 is equal to 70, the CRC generator polynomial is D\hat{ }11+D\hat{ }10+D\hat{ }9+D\hat{ }5+1, and values of the elements in the first distributed CRC interleaver are sequentially as follows: 1, 2, 5, 8, 10, 14, 16, 17, 18, 19, 20, 22, 25, 28, 29, 30, 32, 36, 39, 41, 42, 43, 44, 45, 50, 52, 53, 54, 55, 56, 57, 58, 61, 62, 64, 65, 76, 0, 3, 4, 9, 11, 12, 13, 23, 24, 31, 33, 35, 38, 48, 49, 59, 60, 63, 66, 72, 6, 15, 21, 26, 37, 40, 46, 51, 77, 34, 67, 73, 7, 27, 47, 78, 68, 74, 79, 69, 70, 71, 75, and 80.

According to a second aspect, an embodiment of this disclosure provides a decoding method. The method includes: obtaining a to-be-decoded sequence; checking the to-be-decoded sequence based on a first CRC generator polynomial, where the to-be-decoded sequence is obtained based on a second bit sequence obtained by performing interleaving on a first bit sequence, the first bit sequence includes K1 information bits and L CRC bits, K1 is a positive integer, and L is a positive integer less than 24; and when the check on the to-be-decoded sequence succeeds, performing deinterleaving on the second bit sequence by using a first distributed CRC deinterleaver, to obtain the K1 information bits, where the first distributed CRC deinterleaver corresponds to a first distributed interleaver, the first distributed CRC interleaver includes (K2+L) elements, values of a (K2+L−S)^{th} element to a (K2+L)^{th} element in the first distributed CRC interleaver are sequentially (K2+L−1−S) to (K2+L−1), S is an integer greater than or equal to 0 and less than or equal to L, and K2 is an integer greater than or equal to K1.

In this embodiment of this disclosure, when the check on the to-be-decoded sequence succeeds, deinterleaving is performed on the second bit sequence by using the first distributed CRC deinterleaver, to obtain the K1 information bits. The first distributed CRC deinterleaver supports DCRC encoding with a shorter payload, so that decoding power consumption and resource overheads can be reduced.

In a possible implementation, the first distributed CRC interleaver is obtained by sequentially arranging L element sequences, any two of the L element sequences are a first element sequence and a second element sequence, an element included in the first element sequence is obtained based on a position of an information bit associated with a first check column, and an element included in the second element sequence is obtained based on a position of an information bit associated with a second check column, the first check column and the second check column are any two columns in a check matrix obtained based on the L-length CRC generator polynomial, and when a largest element that is in the first element sequence and that represents the position of the information bit associated with the first check column is greater than a largest element that is in the second element sequence and that represents the position of the information bit associated with the second check column, the first element sequence in the first distributed CRC interleaver is arranged after the second element sequence.

For possible implementations of the second aspect, refer to the possible implementations of the first aspect.

For technical effects brought by the possible implementations of the second aspect, refer to descriptions of technical effects of the possible implementations of the first aspect.

According to a third aspect, an embodiment of this disclosure provides a communication apparatus. The communication apparatus has a function of implementing behavior in the method embodiment in the first aspect. The communication apparatus may be a network device, or may be a component (for example, a processor, a chip, or a chip system) of the network device, or may be a logical module or software that can implement all or a part of functions of the network device. Alternatively, the communication apparatus may be a terminal device, or may be a component (for example, a processor, a chip, or a chip system) of the terminal device, or may be a logical module or software that can implement all or a part of functions of the terminal device. The function of the communication apparatus may be implemented by hardware, or may be implemented by hardware executing corresponding software. The hardware or the software includes one or more modules or units corresponding to the foregoing function. In a possible implementation, the communication apparatus includes a processing module. The processing module is configured to: perform CRC encoding on K1 information bits, to obtain a first bit sequence, where the first bit sequence includes the K1 information bits and L CRC bits, K1 is a positive integer, and L is a positive integer less than 24; and perform interleaving on the first bit sequence by using a first distributed CRC interleaver, to obtain a second bit sequence, where the first distributed CRC interleaver includes (K2+L) elements, values of a (K2+L−S)^{th} element to a (K2+L)^{th} element in the first distributed CRC interleaver are sequentially (K2+L−1−S) to (K2+L−1), S is an integer greater than or equal to 0 and less than or equal to L, and K2 is an integer greater than or equal to K1; or the first distributed CRC interleaver includes a total of (K2+L) natural numbers ranging from 0 to (K2+L−1), P in the first distributed CRC interleaver is before Q, both P and Q are integers greater than or equal to K2, and P is greater than Q. Optionally, the communication apparatus further includes a transceiver module, and the transceiver module is configured to send a signal that carries a to-be-decoded sequence obtained based on the second bit sequence.

For possible implementations of the communication apparatus in the third aspect, refer to the possible implementations of the first aspect.

For technical effects brought by the possible implementations of the third aspect, refer to descriptions of technical effects of the possible implementations of the first aspect.

According to a fourth aspect, an embodiment of this disclosure provides a communication apparatus. The communication apparatus has a function of implementing behavior in the method embodiment in the second aspect. The communication apparatus may be a network device, or may be a component (for example, a processor, a chip, or a chip system) of the network device, or may be a logical module or software that can implement all or a part of functions of the network device. Alternatively, the communication apparatus may be a terminal device, or may be a component (for example, a processor, a chip, or a chip system) of the terminal device, or may be a logical module or software that can implement all or a part of functions of the terminal device. The function of the communication apparatus may be implemented by hardware, or may be implemented by hardware executing corresponding software. The hardware or the software includes one or more modules or units corresponding to the foregoing function. In a possible implementation, the communication apparatus includes a processing module. The processing module is configured to: obtain a to-be-decoded sequence; check the to-be-decoded sequence based on a first CRC generator polynomial, where the to-be-decoded sequence is obtained based on a second bit sequence obtained by performing interleaving on a first bit sequence, the first bit sequence includes K1 information bits and L CRC bits, K1 is a positive integer, and L is a positive integer less than 24; and when the check on the to-be-decoded sequence succeeds, perform deinterleaving on the second bit sequence by using a first distributed CRC deinterleaver, to obtain the K1 information bits, where the first distributed CRC deinterleaver corresponds to a first distributed interleaver, the first distributed CRC interleaver includes (K2+L) elements, values of a (K2+L−S)^{th} element to a (K2+L)^{th} element in the first distributed CRC interleaver are sequentially (K2+L−1−S) to (K2+L−1), S is an integer greater than or equal to 0 and less than or equal to L, and K2 is an integer greater than or equal to K1. Optionally, the communication apparatus further includes a transceiver module, and the transceiver module is configured to carry a signal of the to-be-decoded sequence.

For possible implementations of the communication apparatus in the fourth aspect, refer to the possible implementations of the second aspect.

For technical effects brought by the possible implementations of the fourth aspect, refer to descriptions of technical effects of the possible implementations of the second aspect.

According to a fifth aspect, an embodiment of this disclosure provides another communication apparatus. The communication apparatus includes one or more processors, and the one or more processors are configured to process data or signaling, to enable the method according to either of the first aspect and the second aspect to be implemented.

Optionally, the communication apparatus further includes a memory. The memory stores a program or instructions. When the program or the instructions are executed by the processor, the communication apparatus is enabled to perform the method according to the first aspect or the second aspect. For example, the communication apparatus may be a chip, the processor is a processing circuit in the chip, and the memory is a random-access memory (RAM) or a cache in the chip.

In a possible implementation, in a process of performing the method, a process of sending information (or a signal) in the method may be understood as a process of outputting information based on instructions of the processor. When outputting the information, the processor outputs the information to a transceiver, so that the transceiver transmits the information. After the information is output by the processor, other processing may be further performed on the information before the information arrives at the transceiver. Similarly, when the processor receives input information, the transceiver receives the information, and inputs the information to the processor. Further, after the transceiver receives the information, other processing may be performed on the information before the information is input into the processor.

Operations such as sending and/or receiving related to the processor may be generally understood as outputting based on instructions of the processor, unless otherwise specified, or if the operations do not conflict with actual functions or internal logic of the operations in the related descriptions.

In an implementation process, the processor may be a processor specially configured to perform these methods, or may be a processor, for example, a general-purpose processor, that executes computer instructions in the memory to perform these methods. For example, the processor may be further configured to execute a program stored in the memory. When the program is executed, the communication apparatus is enabled to perform the method according to any one of the first aspect or the possible implementations of the first aspect.

In a possible implementation, the memory is located outside the communication apparatus. In a possible implementation, the memory is located inside the communication apparatus.

In a possible implementation, the processor and the memory may alternatively be integrated into one component. In other words, the processor and the memory may alternatively be integrated together.

In a possible implementation, the communication apparatus further includes the transceiver. The transceiver is configured to: receive a signal, send a signal, or the like.

According to a sixth aspect, this disclosure provides another communication apparatus. The communication apparatus includes a processing circuit and an interface circuit, the interface circuit is configured to obtain data or output data, and the processing circuit is configured to perform the method according to either of the first aspect and the second aspect.

According to a seventh aspect, this disclosure provides a computer-readable storage medium. The computer-readable storage medium stores a computer program, the computer program includes program instructions, and when the program instructions are executed, a computer is enabled to perform the method according to either of the first aspect and the second aspect.

According to an eighth aspect, this disclosure provides a computer program product. The computer program product includes a computer program, the computer program includes program instructions, and when the program instructions are executed, a computer is enabled to perform the method according to either of the first aspect and the second aspect.

According to a ninth aspect, this disclosure provides a chip, including a communication interface and a processor. The communication interface is configured to receive and send a signal of the chip, and the processor is configured to execute computer program instructions, to enable a communication apparatus including the chip to perform the method according to either of the first aspect and the second aspect.

According to a tenth aspect, an embodiment of this disclosure provides a communication system, including the communication apparatus according to any one of the third aspect or the possible implementations of the third aspect, and the communication apparatus according to any one of the fourth aspect or the possible implementations of the fourth aspect.

### BRIEF DESCRIPTION OF DRAWINGS

FIG. 1 is a diagram of a working principle of a downlink low-power wake-up signal of a low-power device;

FIG. 2 is a diagram of an architecture of a communication system to which an embodiment of this disclosure may be applied;

FIG. 3 is a schematic flowchart of a communication system;

FIG. 4 is a flowchart of an encoding method according to an embodiment of this disclosure;

FIG. 5 is a flowchart of another encoding method according to an embodiment of this disclosure;

FIG. 6 is an example of a DCRC encoding matrix corresponding to a first distributed CRC interleaver according to an embodiment of this disclosure;

FIG. 7 is an example of a DCRC encoding matrix corresponding to another first distributed CRC interleaver according to an embodiment of this disclosure;

FIG. 8 is an example of a DCRC encoding matrix corresponding to another first distributed CRC interleaver according to an embodiment of this disclosure;

FIG. 9 is an example of a DCRC encoding matrix corresponding to another first distributed CRC interleaver according to an embodiment of this disclosure;

FIG. 10 is an example of a DCRC encoding matrix corresponding to another first distributed CRC interleaver according to an embodiment of this disclosure;

FIG. 11 is an example of a DCRC encoding matrix corresponding to another first distributed CRC interleaver according to an embodiment of this disclosure;

FIG. 12 is an example of a DCRC encoding matrix corresponding to another first distributed CRC interleaver according to an embodiment of this disclosure;

FIG. 13 is an example of a DCRC encoding matrix corresponding to another first distributed CRC interleaver according to an embodiment of this disclosure;

FIG. 14 is an example of a DCRC encoding matrix corresponding to another first distributed CRC interleaver according to an embodiment of this disclosure;

FIG. 15 is an example of a DCRC encoding matrix corresponding to another first distributed CRC interleaver according to an embodiment of this disclosure;

FIG. 16 is an example of a DCRC encoding matrix corresponding to another first distributed CRC interleaver according to an embodiment of this disclosure;

FIG. 17 is an example of a DCRC encoding matrix corresponding to another first distributed CRC interleaver according to an embodiment of this disclosure;

FIG. 18 is an example of a DCRC encoding matrix corresponding to another first distributed CRC interleaver according to an embodiment of this disclosure;

FIG. 19 is an example of a DCRC encoding matrix corresponding to another first distributed CRC interleaver according to an embodiment of this disclosure;

FIG. 20 is an example of a DCRC encoding matrix corresponding to another first distributed CRC interleaver according to an embodiment of this disclosure;

FIG. 21 is an example of a DCRC encoding matrix corresponding to another first distributed CRC interleaver according to an embodiment of this disclosure;

FIG. 22 is an example of a DCRC encoding matrix corresponding to another first distributed CRC interleaver according to an embodiment of this disclosure;

FIG. 23 is an example of a DCRC encoding matrix corresponding to another first distributed CRC interleaver according to an embodiment of this disclosure;

FIG. 24 is an example of a DCRC encoding matrix corresponding to another first distributed CRC interleaver according to an embodiment of this disclosure;

FIG. 25 is an example of a DCRC encoding matrix corresponding to another first distributed CRC interleaver according to an embodiment of this disclosure;

FIG. 26 is an example of a DCRC encoding matrix corresponding to another first distributed CRC interleaver according to an embodiment of this disclosure;

FIG. 27 is an example of a DCRC encoding matrix corresponding to another first distributed CRC interleaver according to an embodiment of this disclosure;

FIG. 28 is an example of a DCRC encoding matrix corresponding to another first distributed CRC interleaver according to an embodiment of this disclosure;

FIG. 29 is an example of a DCRC encoding matrix corresponding to another first distributed CRC interleaver according to an embodiment of this disclosure;

FIG. 30 is an example of a DCRC encoding matrix corresponding to another first distributed CRC interleaver according to an embodiment of this disclosure;

FIG. 31 is an example of a DCRC encoding matrix corresponding to another first distributed CRC interleaver according to an embodiment of this disclosure;

FIG. 32 is an example of a DCRC encoding matrix corresponding to another first distributed CRC interleaver according to an embodiment of this disclosure;

FIG. 33A and FIG. 33B are a flowchart of another encoding method according to an embodiment of this disclosure;

FIG. 34A and FIG. 34B are a flowchart of another encoding method according to an embodiment of this disclosure;

FIG. 35 is a diagram of a structure of a communication apparatus 3500 according to an embodiment of this disclosure; and

FIG. 36 is a diagram of a structure of another apparatus 360 according to an embodiment of this disclosure.

### DESCRIPTION OF EMBODIMENTS

Terms “first”, “second”, and the like in the specification, claims, and accompanying drawings of this disclosure are merely used to distinguish between different objects, and are not used to describe a specific order. It may be understood that various numbers in embodiments of this disclosure are merely used for differentiation for ease of description, and are not used to limit the scope of embodiments of this disclosure. Sequence numbers of the foregoing processes do not mean an execution order, and the execution order of the processes should be determined based on functions and internal logic of the processes. In addition, terms such as “include” and “have” and any other variants thereof are intended to cover a non-exclusive inclusion. For example, processes, methods, systems, products, or devices that include a series of steps or units are not limited to listed steps or units, but instead, optionally further include steps or units that are not listed, or optionally further include other steps or units inherent to these processes, methods, products, or devices.

An “embodiment” mentioned in this specification means that a particular feature, structure, or characteristic described with reference to the embodiment may be included in at least one embodiment of this disclosure. The phrase shown in various positions in the specification may not necessarily refer to a same embodiment, and is not an independent or optional embodiment exclusive from another embodiment. It may be understood explicitly and implicitly by a person skilled in the art that embodiments described in the specification may be combined with other embodiments. In this disclosure, names of messages are merely used to distinguish between different messages, and should not be understood as a limitation. In other words, a name of any message in this disclosure may be replaced with another name. This is not limited in this disclosure.

Terms used in the following embodiments of this disclosure are merely intended to describe specific embodiments, but are not intended to limit this disclosure. Terms “one”, “a”, “the”, “the foregoing”, “this”, and “the one” of singular forms used in this specification and the appended claims of this disclosure are also intended to include plural forms, unless otherwise specified in the context clearly. It should be further understood that the term “and/or” used in this disclosure indicates and includes any or all possible combinations of one or more listed items. For example, “A and/or B” may represent three cases: only A exists, only B exists, and both A and B exist, where A and B may be singular or plural. The term “a plurality of” used in this disclosure means two or more. In text descriptions of this disclosure, a character “/” usually indicates an “or” relationship between associated objects.

It may be understood that in embodiments of this disclosure, “B corresponding to A” indicates that there is a correspondence between A and B, and B may be determined based on A. However, it should be further understood that determining (or generating) B based on (or according to) A does not mean that B is determined (or generated) only based on (or according to) A, and B may alternatively be determined (or generated) based on (or according to) A and/or other information.

It should be understood that, in this disclosure, an indication includes a direct indication (also referred to as an explicit indication) and an implicit indication. Directly indicating information A means including the information A. Implicitly indicating the information A means indicating the information A by directly indicating information B and based on a correspondence between the information A and the information B. The correspondence between the information A and the information B may be predefined, prestored, pre-burned, or preconfigured.

It should be understood that, in this disclosure, that information C is used to determine information D includes that the information D is determined based only on the information C, and also includes that the information D is determined based on the information C and other information. In addition, that the information C is used to determine the information D may further include an indirect determining case. For example, the information D is determined based on information E, and the information E is determined based on the information C.

In addition, in embodiments of this disclosure, that “a network element A sends information A to a network element B” may be understood as that a destination end of the information A or an intermediate network element in a transmission path between the network element A and the destination end is the network element B, and may include directly or indirectly sending information to the network element B; and that “a network element B receives information A from a network element A” may be understood as that a source end of the information A or an intermediate network element in a transmission path between the network element B and the source end is the network element A, and may include directly or indirectly receiving information from the network element A. Information may undergo necessary processing, for example, a format change, between the source end for sending the information and the destination end. However, the destination end may understand valid information from the source end. Similar descriptions in this disclosure may be understood similarly, and details are not described herein.

For ease of understanding solutions of this disclosure, the following first describes terms and technical solutions in embodiments of this disclosure.

Low-power wake-up signal (LP-WUS): If a main receiver of user equipment (UE) is set to be off or set to be in a deep sleep state before being woken up, power consumption of the UE may be greatly reduced. The wake-up of the UE may be implemented by using a wake-up signal to trigger a low-power wake-up receiver capable of monitoring a wake-up signal with low power consumption. FIG. 1 is a diagram of a working principle of a downlink low-power wake-up signal of a low-power device. As shown in FIG. 1, a main receiver and a low-power wake-up receiver are deployed in UE, and both the main receiver and the low-power wake-up receiver have independent radio frequency (RF) circuits and antennas. The main receiver is configured to send and receive data, and is set to be off or set to be in a deep sleep state if the main receiver is not woken up by a wake-up signal. The low-power wake-up receiver is a supplementary chip for powering on and powering off the main receiver. The low-power wake-up receiver receives an LP-WUS through a separate antenna, which may enable the main receiver to enter an ultra-deep sleep state when traffic activity is limited or no traffic activity exists. The UE wakes up the main receiver after detecting the LP-WUS through the low-power wake-up receiver. For example, before sending data to the UE, a base station may first send an LP-WUS to the UE; and after the main receiver of the UE is woken up, send an NR signal to the UE for data transmission.

Cyclic redundancy check code: The cyclic redundancy check code is widely used in serial transmission (disk and communication). CRC is also used to add several check codes (that is, check bits) to an information code (that is, an information bit), to increase a code distance and improve an error detection and correction capability of an entire coding system. A basic principle of the cyclic redundancy check code is to concatenate an R-bit check code after a K-bit information code, and an entire encoding length is N bits. Therefore, this type of encoding is also referred to as an (N, K) code. For a given (N, K) code, it can be proved that there is a polynomial G (x) whose highest power is N−K=R. A check code of the K-bit information code may be generated based on G (x), and G (x) may be referred to as a CRC generator polynomial (which may be referred to as a generator polynomial for short). A specific process of generating the check code is as follows: it is assumed that sent information is represented by an information polynomial C (X). C (x) is left-shifted by R bits, which may be represented as C (X)*2R. In this way, R bits are left vacant on the right of C (x), which is a position of the check code. A remainder obtained by dividing C (x)*2 by the CRC generator polynomial G (x) is the check code. The CRC generator polynomial is an agreement between a receiver (or a receiving side) and a transmitter (or a transmitting side), that is, a binary number. The number remains unchanged during an entire transmission process. At the transmitter, the CRC generator polynomial is used to perform modulo-2 division on an information polynomial to generate a check code. At the receiver, the CRC generator polynomial is used to perform modulo-2 division on a received encode polynomial to detect an error and determine an error position. The CRC generator polynomial should meet the following conditions: a·A most significant bit and a least significant bit of the CRC generator polynomial need to be 1. b. When any bit of transmitted information (CRC code) is incorrect, a remainder obtained by performing modulo-2 division by using the generator polynomial should not be 0.

The following describes a communication system to which the technical solutions provided in this disclosure are applicable.

The technical solutions provided in this disclosure may be applied to various communication systems, for example, a Narrowband Internet of things (NB-IoT) system, a Global System for Mobile Communications (GSM), an Enhanced Data Rate for GSM Evolution (EDGE) system, a 5th generation (5G) or NR system, a Long-Term Evolution (LTE) system, an LTE frequency-division duplex (FDD) system, a wireless local area network (WLAN) system, a satellite communication system, a future communication system like a 6th generation (6G) mobile communication system, or a converged system of a plurality of systems. The technical solutions provided in this disclosure may be further applied to device-to-device (D2D) communication, vehicle-to-everything (V2X) communication, machine-to-machine (M2M) communication, machine-type communication (MTC), an Internet of things (IoT) communication system, or another communication system. The technical solutions provided in embodiments of this disclosure are also applicable to another communication system related to channel encoding. The foregoing communication systems to which the technical solutions provided in embodiments of this disclosure are applicable are merely examples for description. A communication system to which the technical solutions provided in this disclosure are applicable is not limited thereto. This is uniformly described herein, and details are not described below again.

A first device in the communication system may send a signal to a second device or receive a signal from a third device. The signal may include information, signaling, data, and the like. The device may alternatively be replaced with an entity, a network entity, a communication device, a communication module, a node, a communication node, or the like. In this disclosure, a network element is used as an example for description. The first device may be a network device or a terminal device, the second device may be a network device or a terminal device, and the third device may be a network device or a terminal device. For example, the communication system may include at least one terminal device and at least one network device. The network device may send a downlink signal to the terminal device, and/or the terminal device may send an uplink signal to the network device. It may be understood that the terminal device in this disclosure may be replaced with a first device, the network device may be replaced with a second device, and the terminal device and the network device perform a corresponding communication method in this disclosure.

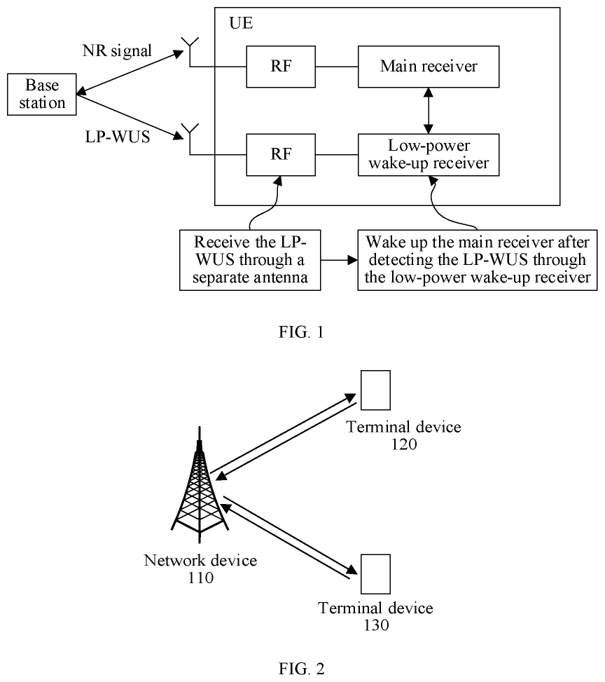

FIG. 2 is a diagram of an architecture of a communication system to which an embodiment of this disclosure may be applied. As shown in FIG. 2, the communication system includes a network device 110, a terminal device 120, and a terminal device 130. The communication system to which embodiments of this disclosure may be applied includes one or more terminal devices. The terminal device 120 and the terminal device 130 are used as examples of the terminal devices in the communication system. FIG. 2 is merely a diagram. A quantity of network devices and a quantity of terminal devices included in the communication system are not limited in embodiments of this disclosure. The terminal device 120 and the terminal device 130 may access the network device 110, and communicate with the network device 110. The technical solutions provided in this disclosure are applicable to a low-power scenario. For example, the terminal device in FIG. 2 is a low-power device.

In embodiments of this disclosure, the terminal device may also be referred to as user equipment (UE), an access terminal, a subscriber unit, a subscriber station, a mobile station, a remote station, a remote terminal, a mobile device, a user terminal, a terminal, a wireless communication device, a user agent, or a user apparatus.

The terminal device may be a device that provides voice/data, for example, a handheld device or a vehicle-mounted device having a wireless connection function. Currently, some examples of the terminal are: a mobile phone, a tablet computer, a notebook computer, a palmtop computer, a mobile Internet device (MID), a wearable device, a virtual reality (VR) device, an augmented reality (AR) device, a wireless terminal in industrial control, a wireless terminal in self-driving, a wireless terminal in a remote medical surgery, a wireless terminal in a smart grid, a wireless terminal in transportation safety, a wireless terminal in a smart city, a wireless terminal in a smart home, a cellular phone, a cordless phone, a Session Initiation Protocol (SIP) phone, a wireless local loop (WLL) station, a personal digital assistant (PDA), a handheld device having a wireless communication function, a compute device or another processing device connected to a wireless modem, a wearable device, a terminal device in a 5G network, a terminal device in a future evolved public land mobile communication network (PLMN), or the like. This is not limited in embodiments of this disclosure.

By way of example and not limitation, in embodiments of this disclosure, the terminal device may alternatively be a wearable device. The wearable device may also be referred to as a wearable intelligent device, and is a general term of a wearable device that is intelligently designed and developed for daily wear by using a wearable technology, for example, glasses, gloves, a watch, clothing, and shoes. The wearable device is a portable device that can be directly worn on the body or integrated into clothes or an accessory of a user. The wearable device is not only a hardware device, but also implements a powerful function through software support, data exchange, and cloud interaction. In a broad sense, wearable intelligent devices include full-featured and large-sized devices that can implement complete or partial functions without depending on smartphones, such as smart watches or smart glasses, and devices that are dedicated to only one type of application function and need to work with other devices such as smartphones, such as various smart bands or smart jewelry for monitoring physical signs.

In embodiments of this disclosure, an apparatus configured to implement a function of the terminal device may be a terminal device, or may be an apparatus that can support the terminal device in implementing the function, for example, a chip system. The apparatus may be installed in the terminal device or used in matching with the terminal device. In embodiments of this disclosure, the chip system may include a chip, or may include a chip and another discrete component. In embodiments of this disclosure, an example in which the apparatus configured to implement the function of the terminal device is a terminal device is merely used for description, and constitutes no limitation on the solutions in embodiments of this disclosure.

In embodiments of this disclosure, the network device may be a device configured to communicate with the terminal device. The network device may also be referred to as an access network device or a radio access network device. For example, the network device may be a base station. In embodiments of this disclosure, the network device may be a radio access network (RAN) node (or device) that enables the terminal device to access a wireless network. The base station may cover any of the following names in a broad sense, or may be replaced with the following names: for example, a RAN node, a NodeB, an evolved NodeB (eNB), a next generation NodeB (gNB), a relay station, an access point, a transmitting and receiving point (TRP), a transmitting point (TP), a primary station, a secondary station, a multi-standard radio (MSR) node, a home base station, a network controller, an access node, a radio node, an access point (AP), a transmission node, a transceiver node, a baseband unit (BBU), a remote radio unit (RRU), an active antenna unit (AAU), a remote radio head (RRH), a central unit (CU), a distributed unit (DU), a radio unit (RU), and a positioning node. The base station may be a macro base station, a micro base station, a relay node, a donor node, an analogue, or a combination thereof. The base station may alternatively be a communication module, a modem, or a chip disposed in the foregoing device or apparatus. The base station may alternatively be a mobile switching center, a device that bears a base station function in D2D, V2X, and M2M communication, a network side device in a 6G network, a device that bears a base station function in a future communication system, or the like. The base station may support networks using a same access technology or different access technologies. Optionally, the RAN node may alternatively be a server, a wearable device, a vehicle, a vehicle-mounted device, or the like. For example, an access network device in a vehicle-to-everything (V2X) technology may be a road side unit (RSU). A specific technology and a specific device form that are used by the network device are not limited in embodiments of this disclosure. The base station may be fixed or mobile. For example, a helicopter or an uncrewed aerial vehicle may be configured as a mobile base station, and one or more cells may move based on a position of the mobile base station. In other examples, a helicopter or an uncrewed aerial vehicle may be configured as a device for communicating with another base station.

In some deployments, the network device mentioned in embodiments of this disclosure may be a device including a CU or a DU, a device including a CU and a DU, or a device including a CU control plane (CU-CP) node, a CU user plane (CU-UP) node, and a DU node. For example, the network device may include a gNB-CU-CP, a gNB-CU-UP, and a gNB-DU.

In some deployments, a plurality of RAN nodes cooperate to assist the terminal in implementing radio access, and different RAN nodes respectively implement a part of functions of the base station. For example, the RAN node may be a CU, a DU, a CU-CP, a CU-UP, or an RU. The CU and the DU may be separately disposed, or may be included in a same network element, for example, a BBU. The RU may be included in a radio frequency device or a radio frequency unit, for example, included in an RRU, an AAU, or an RRH.

In embodiments of this disclosure, an apparatus configured to implement a function of the network device may be a network device, or may be an apparatus that can support the network device in implementing the function, for example, a chip system, a hardware circuit, a software module, or a combination of the hardware circuit and the software module. The apparatus may be installed in the network device or used in matching with the network device. In embodiments of this disclosure, an example in which the apparatus configured to implement the function of the network device is a network device is merely used for description, and constitutes no limitation on the solutions in embodiments of this disclosure.

It should be noted that a network architecture described in embodiments of this disclosure is intended to describe the technical solutions in embodiments of this disclosure more clearly, and does not constitute a limitation on the technical solutions in embodiments of this disclosure. A person of ordinary skill in the art may learn that the technical solutions provided in embodiments of this disclosure are also applicable to a similar technical problem as a network architecture evolves and a new service scenario emerges.

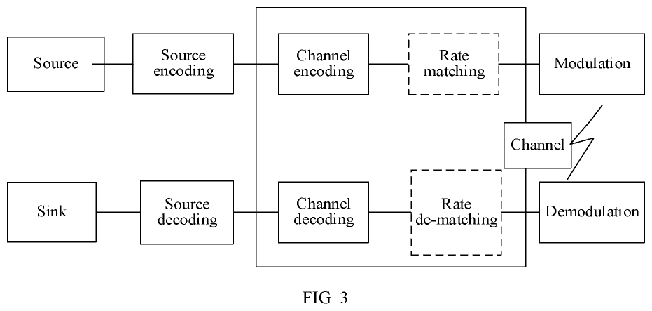

FIG. 3 is a schematic flowchart of a communication system. As shown in FIG. 3, at a transmitting side, a source is sent after sequentially undergoing source encoding, channel encoding rate matching (an optional step), and modulation. At a receiving side, the source is output to a sink after sequentially undergoing demodulation, rate de-matching (an optional step), channel decoding, and source decoding. Embodiments of this disclosure mainly relate to channel encoding and channel decoding (referred to as channel encoding/decoding for short). A channel encoding part is between source encoding and modulation, and is responsible for performing channel encoding on a bit generated by a source. A channel decoding part is between demodulation and source decoding, and is responsible for restoring a source bit stream.

In a low-power scenario to which the technical solutions provided in this disclosure are applied, a low-power device (for example, a terminal device) may use only one channel coding scheme, that is, a data channel and a control channel use a same encoding policy. A main principle of the technical solutions provided in this disclosure is as follows: a DCRC interleaver that supports a smaller payload and a shorter CRC length is used for channel encoding, to meet requirements of a low-power device for energy efficiency, coverage, and a false alarm rate (FAR). In a possible implementation, both the data channel and the control channel use the channel coding scheme provided in this disclosure. In a possible implementation, an LP-WUS also uses the channel coding scheme. For example, when a quantity of to-be-sent payload bits at the transmitting side is reduced, a 24-bit CRC is not needed. Therefore, the DCRC interleaver also needs to be correspondingly shortened and redesigned. A CRC length may be 6, 11, 16, or another value. This is not limited in this disclosure. A size of the payload may be less than or equal to 70.

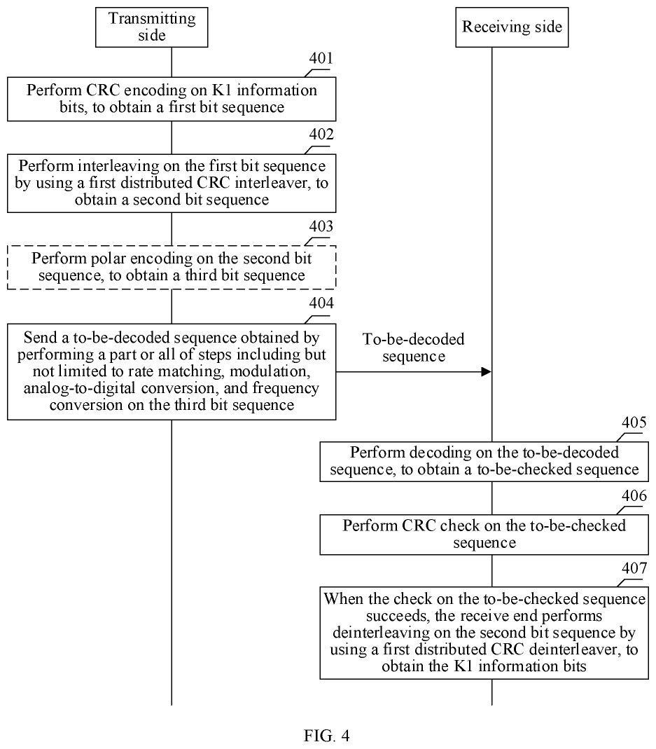

The following first describes the technical solutions provided in this disclosure with reference to FIG. 4. FIG. 4 is a flowchart of an encoding method according to an embodiment of this disclosure. As shown in FIG. 4, the method includes the following steps.

401: A transmitting side performs CRC encoding on K1 information bits, to obtain a first bit sequence.

In a possible implementation, the transmitting side is a network device, and a receiving side is a terminal device. In a possible implementation, the transmitting side is a terminal device, and the receiving side is a network device. The first bit sequence includes the K1 information bits and L CRC bits, K1 is a positive integer, and L is a positive integer less than 24. For example, the K1 information bits may be obtained through source encoding performed by the transmitting side on a plurality of to-be-sent bits, and the K1 information bits are bits to be channel encoded.

In a possible implementation, L is equal to 6, 11, or 16. Alternatively, L may be another integer less than 24. This is not limited in this disclosure.

In a possible implementation, K1 is equal to 32, 40, 48, 54, 64, 70, or 100. Alternatively, K1 may be another integer less than 140. This is not limited in this disclosure.

402: The transmitting side performs interleaving on the first bit sequence by using a first distributed CRC interleaver, to obtain a second bit sequence.

The first distributed CRC interleaver includes (K2+L) elements, values of a (K2+L−S)^{th} element to a (K2+L)^{th} element in the first distributed CRC interleaver are sequentially (K2+L−1−S) to (K2+L−1), S is an integer greater than or equal to 0 and less than or equal to L, and K2 is an integer greater than or equal to K1. (K2+L) is less than 164. Alternatively, the first distributed CRC interleaver includes a total of (K2+L) natural numbers ranging from 0 to (K2+L−1), P in the first distributed CRC interleaver is before Q, both P and Q are integers greater than or equal to K2, and P is greater than Q. Alternatively, the first distributed CRC interleaver includes a total of (K2+L) natural numbers from 1 to (K2+L), P in the first distributed CRC interleaver is before Q, both P and Q are integers greater than or equal to K2, and P is greater than Q. For example, K2 is equal to 70, P is 75, and Q is 72. In this specification, the element in the DCRC interleaver may start from 0, that is, O represents a first position. Alternatively, the element in the DCRC interleaver may start from 1, that is, 1 represents a first position. This is not limited herein.

In a possible implementation, K2 is equal to 70 or 100. Alternatively, K2 may be another integer less than 140 and greater than or equal to K1. This is not limited in this disclosure. For example, K2 is equal to 70, L=6, S=0, and a 76th element (that is, the last element) in the first distributed CRC interleaver is 75, where a 75^{th} element in the first distributed CRC interleaver may not be 74. For example, K2 is equal to 70, L=11, S=1, an 80^{th} element (that is, the last element) in the first distributed CRC interleaver is 79, and an 81^{st} element is 80, where a 79^{th} element in the first distributed CRC interleaver may not be 78, or a 78^{th} element in the first distributed CRC interleaver may not be 77, or a 77^{th} element in the first distributed CRC interleaver may not be 76.

In a possible implementation, the first distributed CRC interleaver is obtained by sequentially arranging L element sequences, any two of the L element sequences are a first element sequence and a second element sequence, an element included in the first element sequence is obtained based on a position of an information bit associated with a first check column, and an element included in the second element sequence is obtained based on a position of an information bit associated with a second check column, the first check column and the second check column are any two columns in a check matrix obtained based on an L-length CRC generator polynomial, and when a largest element that is in the first element sequence and that represents the position of the information bit associated with the first check column is greater than a largest element that is in the second element sequence and that represents the position of the information bit associated with the second check column, the first element sequence in the first distributed CRC interleaver is arranged after the second element sequence. For example, the second element sequence is [2, 3, 40, 72], where the second element sequence indicates the first check column (that is, a 73^{rd} column of the check matrix is associated with 2^{nd}, 3^{rd}, and 40^{th} information bits); and the first element sequence is [1, 60, 71], where the first element sequence indicates the second check column (that is, a 72^{nd} column of the check matrix is associated with 1^{st} and 60^{th} information bits). In this implementation, when the largest element that is in the first element sequence and that represents the position of the information bit associated with the first check column is greater than the largest element that is in the second element sequence and that represents the position of the information bit associated with the second check column, the first element sequence in the first distributed CRC interleaver is arranged after the second element sequence, so that the receiving side can detect a CRC check failure earlier during decoding, thereby reducing decoding power consumption.

An example of obtaining the first distributed CRC interleaver based on the L-length CRC generator polynomial is as follows: the transmitting side obtains positions of information bits associated with each column of the check matrix generated based on the L-length CRC generator polynomial. Given one L-length CRC generator polynomial gL, for example, gL=D\hat{ }6+D\hat{ }5+1, the CRC generator polynomial corresponds to a matrix Gcrc with K rows and (K+L) columns. First K rows and K columns of Gerc are a unit matrix, and last K rows and L columns of Gerc are a check matrix generated based on the CRC generator polynomial, used to generate L-bit CRC check bits. K is equal to 70, and L is equal to 6. A first check column of the check matrix (a 71^{st} column of the matrix Gcrc) is associated with 0^{th}, 2^{nd}, 3^{rd}, 4^{th}, 5^{th}, 6^{th}, 7^{th}, 13^{th}, 18^{th}, 19^{th}, 23^{rd}, 25^{th} 28^{th}, 29^{th}, 30^{th}, 31^{st}, 33^{rd}, 37^{th}, 38^{th}, 39^{th}, 42^{nd}, 45^{th}, 47^{th}, 48^{th}, 50^{th}, 51^{st}, 52^{nd}, 54^{th}, 55^{th}, 58^{th}, 59^{th}, 61^{st}, 63^{rd}, 65^{th}, 66^{th}, 67^{th}, 68^{th}, and 69^{th} information bits. A second check column of the check matrix (a 72^{nd} column of the matrix Gcrc) is associated with 1^{st}, 2^{nd}, 3^{rd}, 8^{th}, 14^{th}, 20^{th}, 24^{th}, 26^{th}, 32^{nd}, 34^{th}, 40^{th}, 43^{rd}, 46^{th}, 49^{th}, 53^{rd}, 56^{th}, 60^{th}, 62^{nd}, and 64^{th} information bits. A third check column of the check matrix (a 73^{rd} column of the matrix Gcrc) is associated with 8^{th}, 9^{th}, 14^{th}, 15^{th}, 21^{st}, 27^{th}, 35^{th}, 41^{st}, 44^{th}, and 57^{th} information bits. A fourth check column of the check matrix (a 74^{th} column of the matrix Gcrc) is associated with 10^{th}, 16^{th}, 22^{nd}, 27^{th}, and 36^{th} information bits. A fifth check column of the check matrix (a 75^{th} column of the matrix Gcrc) is associated with 11^{th}, 17^{th}, 28^{th}, 31^{st}, 39^{th}, and 65^{th} information bits. A sixth check column of the check matrix (a 76^{th} column of the matrix Gcrc) is associated with 5^{th}, 12^{th}, 25^{th}, and 34^{th} information bits. The transmitting side obtains an element sequence #1 [0, 2, 3, 4, 5, 6, 7, 13, 18, 19, 23, 25, 28, 29, 30, 31, 33, 37, 38, 39, 42, 45, 47, 48, 50, 51, 52, 54, 55, 58, 59, 61, 63, 65, 66, 67, 68, 69] based on positions of the information bits associated with the first check column, obtains an element sequence #2 [1, 2, 3, 8, 14, 20, 24, 26, 32, 34, 40, 43, 46, 49, 53, 56, 60, 62, 64] based on positions of the information bits associated with the second check column, obtains an element sequence #3 [8, 9, 14, 15, 21, 27, 35, 41, 44, 57] based on positions of the information bits associated with the third check column, obtains an element sequence #4 [10, 16, 22, 27, 36] based on positions of the information bits associated with the fourth check column, obtains an element sequence #5 [11, 17, 28, 31, 39, 65] based on positions of the information bits associated with the fifth check column, and obtains an element sequence #6 [5, 12, 25, 34] based on positions of the information bits associated with the sixth check column. The transmitting side arranges the element sequences corresponding to the check columns in ascending order of largest values in the element sequences: [5, 12, 25, 34], [10, 16, 22, 27, 36], [8, 9, 14, 15, 21, 27, 35, 41, 44, 57], [1, 2, 3, 8, 14, 20, 24, 26, 32, 34, 40, 43, 46, 49, 53, 56, 60, 62, 64], [11, 17, 28, 31, 39, 65], and [0, 2, 3, 4, 5, 6, 7, 13, 18, 19, 23, 25, 28, 29, 30, 31, 33, 37, 38, 39, 42, 45, 47, 48, 50, 51, 52, 54, 55, 58, 59, 61, 63, 65, 66, 67, 68, 69]. The transmitting side packs [5, 12, 25, 34] and a column position (that is, 75) of the sixth check column as a whole and places the whole in first five positions; packs [10, 16, 22, 27, 36] and a column position (73) of the fourth check column as a whole and places the whole after the first packed sequence; packs [8, 9, 14, 15, 21, 27, 35, 41, 44, 57] and a column position (72) of the third check column as a whole and places the whole after the second packed sequence; packs [1, 2, 3, 8, 14, 20, 24, 26, 32, 34, 40, 43, 46, 49, 53, 56, 60, 62, 64] and a column position (71) of the second check column as a whole and places the whole after the third packed sequence, where it is noted that an element that already exists in the previous packet needs to be removed from elements in the subsequent packet; and so on, to obtain a final DCRC interleaver.

403: The transmitting side performs polar encoding on the second bit sequence, to obtain a third bit sequence.

An existing polar encoding method may be used by the transmitting side to perform polar encoding on the second bit sequence. Details are not described herein. Step 403 is optional. The transmitting side may perform encoding on the second bit sequence in another encoding scheme, or may not perform encoding on the second bit sequence. It should be noted that, this step is an optional step, and is necessary only when polar encoding needs to be performed on the second bit sequence; and if unnecessary, this step may be omitted in an actual encoding process. In this case, the third bit sequence in step 404 is the second bit sequence.

404: The transmitting side sends a to-be-decoded sequence obtained by performing a part or all of steps including but not limited to rate matching, modulation, analog-to-digital conversion, and frequency conversion on the third bit sequence.

Correspondingly, the receiving side receives the to-be-decoded sequence from the transmitting side. The obtained to-be-decoded sequence sent by the transmitting side may be a data signal that carries the to-be-decoded sequence and that is sent through a data channel, where the K1 information bits may be data sent by the transmitting side to the receiving side; or may be a control signal that carries the to-be-decoded sequence and that is sent through a control channel, where the K1 information bits may be control information sent by the transmitting side to the receiving side.

It should be noted that, the rate matching step in step 404 is optional. If an encoding code length is the same as a code length of a target code, the rate matching is not needed. Because this embodiment of this disclosure does not focus on step 404, details are not described herein. For example, in a possible implementation, a person skilled in the art may also refer to practices in another technology.

405: The receiving side performs decoding on the to-be-decoded sequence, to obtain a to-be-checked sequence.

The receiving side may obtain the to-be-decoded sequence based on a signal that is from the transmitting side and that carries the to-be-decoded sequence. This is not limited in this disclosure. The to-be-decoded sequence is obtained by performing polar encoding on the second bit sequence, and the to-be-checked sequence may be the second bit sequence.

406: The receiving side performs CRC check on the to-be-checked sequence.

In a possible implementation, step 401 is as follows: the transmitting side performs CRC encoding on the K1 information bits based on the CRC generator polynomial, to obtain the first bit sequence; and step 406 is as follows: the receiving side performs CRC check on the to-be-checked sequence based on the CRC generator polynomial.

407: When the check on the to-be-checked sequence succeeds, the receiving side performs deinterleaving on the second bit sequence by using a first distributed CRC deinterleaver, to obtain the K1 information bits.

When the check on the to-be-checked sequence succeeds, the to-be-checked sequence is the second bit sequence. The first distributed CRC deinterleaver corresponds to the first distributed interleaver. In other words, the first distributed CRC deinterleaver is obtained based on the first distributed interleaver. It is a common technical means in this field to obtain, based on an interleaver, a deinterleaver corresponding to the interleaver. A relationship between the interleaver and the deinterleaver is described in an example herein: if an interleaver is [2, 4, 1, 3] (that is, a 2^{nd} position is interleaved to the first bit, a 4^{th} position is interleaved to the second bit, a 1^{st} position is interleaved to the third bit, and a 3^{rd} position is interleaved to the last bit), a corresponding deinterleaver is [3, 1, 4, 2]. That is, in an interleaved sequence, a 3^{rd} position is adjusted to the first bit, a 1^{st} position is adjusted to the second bit, a 4^{th} position is adjusted to the third bit, a 2^{nd} position is adjusted to the last bit, and a sequence before interleaving may be obtained.

In a possible implementation, when the check on the to-be-checked sequence fails, the receiving side stops further parsing the to-be-checked sequence, for example, deinterleaving. In other words, when the check on the to-be-checked sequence fails, the decoding is terminated in advance. Optionally, the receiving side sends, to the transmitting side, information indicating that the receiving side does not correctly receive the to-be-decoded sequence.

In this embodiment of this disclosure, cyclic redundancy check CRC encoding is performed on the K1 information bits, to obtain the first bit sequence. A quantity of CRC check bits is less than 24. Interleaving is performed on the first bit sequence by using the first distributed CRC interleaver. The first distributed CRC deinterleaver supports DCRC encoding with a shorter payload, so that decoding power consumption and resource overheads can be reduced.

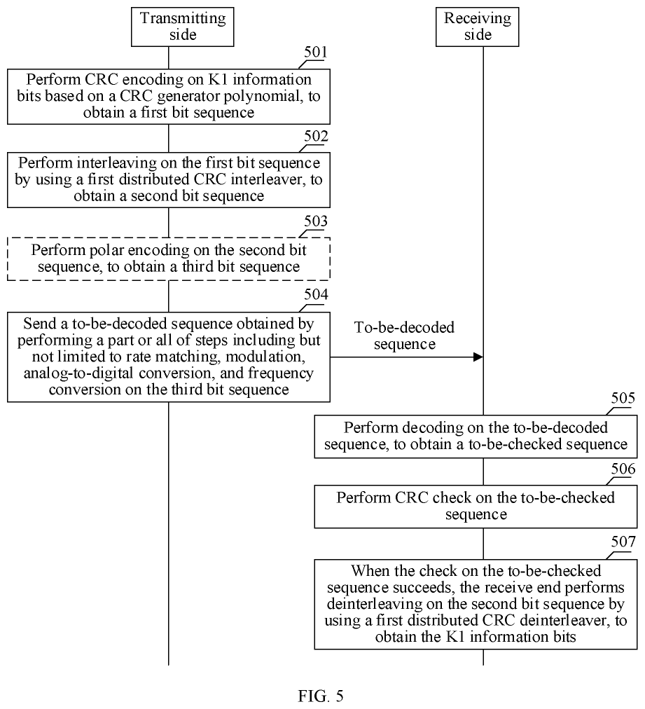

FIG. 5 is a flowchart of another encoding method according to an embodiment of this disclosure. A method procedure in FIG. 5 is a possible implementation of the method described in FIG. 4. As shown in FIG. 5, the method includes the following steps.

501: A transmitting side performs CRC encoding on K1 information bits based on a CRC generator polynomial, to obtain a first bit sequence.

In a possible implementation, the transmitting side is a network device, and a receiving side is a terminal device. In a possible implementation, the transmitting side is a terminal device, and the receiving side is a network device. The first bit sequence includes the K1 information bits and L CRC bits, K1 is a positive integer, and L is a positive integer less than 24. For example, the K1 information bits may be obtained through source encoding performed by the transmitting side on a plurality of to-be-sent bits, and the K1 information bits are bits to be channel encoded. In a possible implementation, L is equal to 6, 11, or 16. Alternatively, L may be another integer less than 24. This is not limited in this disclosure. In a possible implementation, K1 is equal to 32, 40, 48, 54, 64, 70, or 100. Alternatively, K1 may be another integer less than 140. This is not limited in this disclosure.

For example, the CRC generator polynomial is any one of the following:
D\hat{ }6+D\hat{ }5+1, or 43 (hex), where 43 (hex) is a hexadecimal representation of the CRC generator polynomial;
D\hat{ }6+D\hat{ }5+D\hat{ }4+D\hat{ }3+1, or 4F (hex), where 4F (hex) is a hexadecimal representation of the CRC generator polynomial;

$$D \hat{} 6 + D \hat{} 4 + D \hat{} 3 + D + 1 , or 6 D ( hex ) ;$$

$$D \hat{} 6 + D \hat{} 3 + D \hat{} 2 + D + 1 , or 79 ( hex ) ;$$

$$D \hat{} 6 + D \hat{} 5 + D \hat{} 2 + 1 , or 53 ( hex ) ;$$

$$D \hat{} 6 + D \hat{} 5 + D \hat{} 4 + D \hat{} 2 + 1 , or 57 ( hex ) ;$$

$$D \hat{} 6 + D \hat{} 3 + D \hat{} 2 + 1 , or 59 ( hex ) ;$$

$$D \hat{} 6 + D \hat{} 5 + D \hat{} 3 + D \hat{} 2 + 1 , or 5 B ( hex ) ;$$

$$D \hat{} 6 + D \hat{} 5 + D \hat{} 4 + D \hat{} 3 + D \hat{} 2 + 1 , or 5 F ( hex ) ;$$

$$D \hat{} 6 + D \hat{} 5 + D \hat{} 4 + D \hat{} 3 + D + 1 , or 6 F ( hex ) ;$$

$$D \hat{} 6 + D \hat{} 4 + D \hat{} 2 + D + 1 , or 75 ( hex ) ;$$

$$D \hat{} 11 + D \hat{} 10 + D \hat{} 9 + D \hat{} 5 + 1 , or 847 ( hex ) ;$$

$$D \hat{} 11 + D \hat{} 7 + D \hat{} 6 + D \hat{} 2 + 1 , or A 31 ( hex ) ;$$

$$D \hat{} 11 + D \hat{} 10 + D \hat{} 9 + D \hat{} 6 + D \hat{} 4 + D \hat{} 2 + 1 , or AA 7 ( hex ) ;$$

$$D \hat{} 11 + D \hat{} 10 + D \hat{} 9 + D \hat{} 7 + D \hat{} 5 + D + 1 , or D 57 ( hex ) ;$$

$$D \hat{} 11 + D \hat{} 9 + D \hat{} 8 + D \hat{} 6 + D \hat{} 5 + D + 1 , or C 6 D ( hex ) ;$$

$$D \hat{} 11 + D \hat{} 10 + D \hat{} 9 + D \hat{} 8 + D \hat{} 7 + D \hat{} 5 + D \hat{} 4 + D + 1 , or CDF ( hex ) ;$$

$$D \hat{} 11 + D \hat{} 10 + D \hat{} 3 + D + 1 , or D 03 ( hex ) ;$$

$$D \hat{} 11 + D \hat{} 5 + D \hat{} 3 + D + 1 , or D 41 ( hex ) ;$$

$$D \hat{} 11 + D \hat{} 10 + D \hat{} 9 + D \hat{} 8 + D \hat{} 6 + D \hat{} 5 + D \hat{} 3 + D + 1 , or D 6 F ( hex ) ;$$

$$D \hat{} 11 + D \hat{} 10 + D \hat{} 8 + D \hat{} 7 + D \hat{} 6 + D \hat{} 5 + D \hat{} 3 + D + 1 , or D 7 B ( hex ) ;$$

$$D \hat{} 11 + D \hat{} 9 + D \hat{} 7 + D \hat{} 6 + D \hat{} 5 + D \hat{} 4 + D \hat{} 3 + D + 1 , or DF 5 ( hex ) ;$$

$$D \hat{} 11 + D \hat{} 10 + D \hat{} 9 + D \hat{} 7 + D \hat{} 6 + D \hat{} 3 + D \hat{} 2 + D + 1 , or F 37 ( hex ) ;$$

$$D \hat{} 11 + D \hat{} 8 + D \hat{} 6 + D \hat{} 5 + D \hat{} 4 + D \hat{} 3 + D \hat{} 2 + D + 1 , or FE 9 ( hex ) ;$$

$$and$$

$$D \hat{} 16 + D \hat{} 12 + D \hat{} 5 + 1 , or 10811 ( hex ) ;$$

502: The transmitting side performs interleaving on the first bit sequence by using a first distributed CRC interleaver, to obtain a second bit sequence.

For step 502, refer to step 402 in FIG. 4. The first distributed CRC interleaver may be obtained based on the CRC generator polynomial. An example of obtaining the first distributed CRC interleaver based on the CRC generator polynomial is as follows: first, a check matrix (with K rows and L columns, where K=16 and L−3 are used as an example below) corresponding to an L-length CRC generator polynomial is calculated. Then, positions of message bits associated with a 1^{st} check column (that is, a 1^{st} column of the check matrix) are packed into a group, and are interleaved to the front as a whole (for example, if the 1^{st} check column is associated with the message bits [1, 2, 3, 4, 5, 6, 7, 8], [1, 2, 3, 4, 5, 6, 7, 8] and a position K+1=17 of the 1^{st} check column are placed in the first nine positions as a whole). Similarly, positions of message bits associated with a 2^{nd} check column and a position of the 2^{nd} check column are packed as a whole and placed after the first packed sequence. For example, if the positions of the message bits associated with the 2^{nd} check column are [7, 9, 11, 16], the three message positions [9, 11, 16] and the position K+2=16+2=18 of the 2^{nd} check column are packed and placed after the first packet. It is noted that the message bit 7 in the message positions [7, 9, 11, 16] associated with the 2^{nd} check column is already included in the first packet, and therefore needs to be removed from the second packet. Next, the existing message positions in the previous packets are removed from positions [5, 8, 10, 11, 12, 13, 14, 15, 16] of message bits associated with a 3^{rd} check column, and then the positions and a position K+3=16+3=19 of the 3^{rd} check column are packed as a whole and placed after all the previous packets, that is, the six bits [10, 12, 13, 14, 15, 19] are placed after the second packet, to obtain a final DCRC interleaver. It is noted that the DCRC interleaver and the CRC generator polynomial are used, a length of the message bits is K, and a length of the DCRC interleaver is equal to (K+L). In the foregoing example, distributed CRC encoding can be performed on a message whose K is less than or equal to 16 (a maximum of 16 is supported).

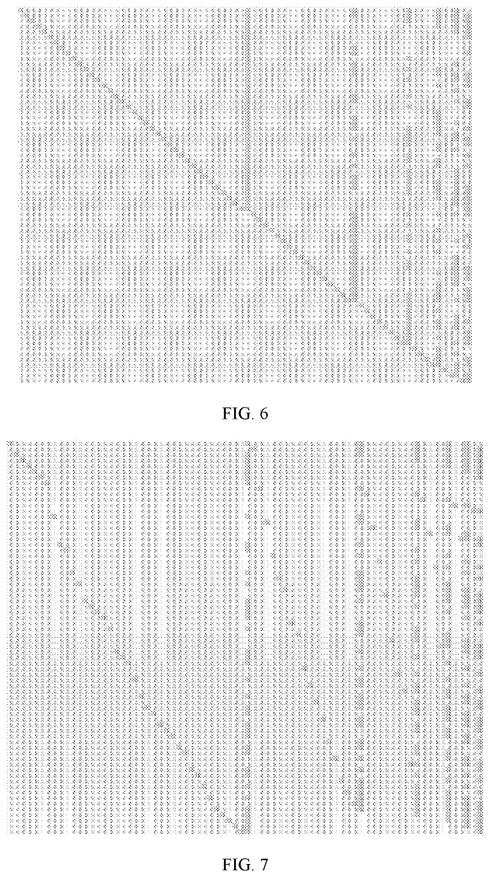

Given one L-length CRC generator polynomial gL, for example, gL=D\hat{ }6+D\hat{ }5+1, the CRC generator polynomial corresponds to one matrix Gcrc with K rows and (K+L) columns. First K rows and K columns of Gerc are a unit matrix, and last K rows and L columns of Gerc are a check matrix generated based on the CRC generator polynomial, where the check matrix is used to generate L-bit CRC check bits. That the transmitting side performs interleaving on the first bit sequence by using the first distributed CRC interleaver, to obtain the second bit sequence may be: the first bit sequence (including the K1 information bits and the L CRC bits) is interleaved by using the first distributed CRC interleaver, to obtain the second bit sequence (that is, an interleaved CRC encoding sequence). A DCRC encoding matrix GDcrc corresponding to the first distributed CRC interleaver may be in the following two forms: one form is an upper triangular GDcrc1. To be specific, DCRC interleaving is performed on both the K rows and the (K+L) columns of Gcrc, where an interleaver used for interleaving of the K rows is an interleaver including K elements whose values are greater than or equal to (76-K) and that are read from the DCRC interleaver in a natural order in a nested manner, and an interleaver used for interleaving of the (K+L) columns is the foregoing (K+L)-length DCRC interleaver. The other form is also a matrix with K rows and (K+L) columns, but is not the upper triangle, that is, GDcrc2, where the matrix is generated by performing interleaving only on the (K+L) columns of Gcrc, not on the K rows of the matrix. If the K1 information bits are a=a0, a1, a2, . . . , and a69, that is, payload bits are K1=70 bits, and a sequence of a obtained through DCRC encoding is a bit sequence b=b0, b1, b2, . . . , and b75 with a length of K+L=70+6=76, b=a·GDcrc1 or b=a·GDcrc2. GDcrc1 is an upper triangular matrix shown in FIG. 6. FIG. 6 is an example of a DCRC encoding matrix corresponding to a first distributed CRC interleaver according to an embodiment of this disclosure.

GDcrc2 is a non-upper triangular matrix shown in FIG. 7, where interleaving is only performed on columns of Gcrc. FIG. 7 is an example of a DCRC encoding matrix corresponding to another first distributed CRC interleaver according to an embodiment of this disclosure. An advantage of GDcrc2 is that it is more convenient to read the DCRC encoding matrix in a nested manner. For a payload whose K is less than 70, first (70−K) rows of the matrix need to be skipped, and DCRC encoding is performed by using only last K rows of the matrix. However, if GDcrc1 intends to support DCRC encoding when K is less than 70 bits, two steps are needed to read a submatrix with K rows and (K+L) columns. A first step is to determine, based on the foregoing DCRC interleaver (that is, the first distributed CRC interleaver), an element whose element value is greater than or equal to (70−K) (that is, skip an element less than (70−K)), to form a K-length sequence. A second step is to select rows at corresponding positions from GDcrc1 based on the K-length sequence obtained in the first step, to form the DCRC encoding matrix.

In a possible implementation, the transmitting side multiplies a matrix corresponding to the K1 information bits by the DCRC encoding matrix corresponding to the first distributed CRC interleaver, to obtain the second bit sequence. For example, the matrix corresponding to the K1 information bits is a=a0, a1, a2, . . . , and a69, GDcrc1 is the DCRC encoding matrix corresponding to the first distributed CRC interleaver, and the second bit sequence b=a−GDcrc1. For another example, the matrix corresponding to the K1 information bits is a=a0, a1, a2, . . . , and a69, GDcrc2 is the DCRC encoding matrix corresponding to the first distributed CRC interleaver, and the second bit sequence b-a-GDcrc2.

503: The transmitting side performs polar encoding on the second bit sequence, to obtain a third bit sequence.

504: The transmitting side sends a to-be-decoded sequence obtained by performing a part or all of steps including but not limited to rate matching, modulation, analog-to-digital conversion, and frequency conversion on the third bit sequence.

505: The receiving side performs decoding on the to-be-decoded sequence, to obtain a to-be-checked sequence.

506: The receiving side performs CRC check on the to-be-checked sequence.

507: When the check on the to-be-checked sequence succeeds, the receiving side performs deinterleaving on the second bit sequence by using a first distributed CRC deinterleaver, to obtain the K1 information bits.

For step 503 to step 507, refer to step 403 to step 407 in FIG. 4. In a possible implementation, when the check on the to-be-checked sequence fails, the decoding is terminated in advance.

In this embodiment of this disclosure, CRC encoding is performed on the K1 information bits based on the CRC generator polynomial, to obtain the first bit sequence. A quantity of CRC check bits is less than 24. Interleaving is performed on the first bit sequence by using the first distributed CRC interleaver. The first distributed CRC deinterleaver supports DCRC encoding with a shorter payload, so that decoding power consumption can be reduced.

The following describes examples of the CRC generator polynomial and examples of the first distributed CRC interleaver obtained based on the CRC generator polynomial.

Example 1: L is equal to 6, K2 is equal to 70, the CRC generator polynomial is D\hat{ }6+D\hat{ }5+1, and values of the elements in the first distributed CRC interleaver obtained based on the CRC generator polynomial are sequentially as follows: 0, 2, 3, 4, 5, 6, 7, 13, 18, 19, 23, 25, 28, 29, 30, 31, 33, 37, 38, 39, 42, 45, 47, 48, 50, 51, 52, 54, 55, 58, 59, 61, 63, 65, 66, 67, 68, 69, 70, 1, 8, 14, 20, 24, 26, 32, 34, 40, 43, 46, 49, 53, 56, 60, 62, 64, 71, 9, 15, 21, 27, 35, 41, 44, 57, 72, 10, 16, 22, 36, 73, 11, 17, 74, 12, and 75.

An example of the DCRC encoding matrix GDcrc corresponding to the first distributed CRC interleaver is the upper triangular matrix shown in FIG. 6. Another example of the DCRC encoding matrix GDcrc corresponding to the first distributed CRC interleaver is the non-upper triangular matrix shown in FIG. 7.

The first distributed CRC interleaver in Example 1 is obtained based on D\hat{ }6+D\hat{ }5+1. A manner of obtaining the first distributed CRC interleaver in Example 1 based on D\hat{ }6+D\hat{ }5+1 may be similar to the manner in the example of obtaining the first distributed CRC interleaver based on the CRC generator polynomial in step 502. Details are not described herein again.

Example 1′: L is equal to 6, K2 is equal to 70, the CRC generator polynomial is D\hat{ }6+D\hat{ }5+1, and values of the elements in the first distributed CRC interleaver obtained based on the CRC generator polynomial are sequentially as follows: 0, 1, 2, 8, 13, 14, 18, 20, 23, 24, 25, 26, 28, 32, 33, 34, 37, 40, 42, 43, 45, 46, 47, 49, 50, 53, 54, 56, 58, 60, 61, 62, 63, 64, 65, 71, 3, 9, 15, 19, 21, 27, 29, 35, 38, 41, 44, 48, 51, 55, 57, 59, 66, 72, 4, 10, 16, 22, 30, 36, 39, 52, 67, 73, 5, 11, 17, 31, 68, 74, 6, 7, 69, 70, 12, and 75.

The first distributed CRC interleaver in Example 1′ is obtained based on D\hat{ }6+D\hat{ }5+1. A manner of obtaining the first distributed CRC interleaver in Example 1′ based on D\hat{ }6+D\hat{ }5+1 may be similar to the manner in the example of obtaining the first distributed CRC interleaver based on the L-length CRC generator polynomial in step 402. Details are not described herein again. The first distributed CRC interleaver in Example 1 and the first distributed CRC interleaver in Example 1′ are obtained based on a same CRC generator polynomial, and a difference lies in that: when the first distributed CRC interleaver in Example 1 is obtained based on D\hat{ }6+D\hat{ }5+1, positions of message bits associated with check columns and positions of the check columns are packed as a whole in a sequence of the positions of the check columns. When the first distributed CRC interleaver in Example 1′ is obtained based on D\hat{ }6+D\hat{ }5+1, positions of message bits associated with check columns and positions of the check columns are packed as a whole in ascending order of largest values (that is, positions of last message bits checked in the check columns) in element sequences corresponding to the check columns. It can be learned by comparing Example 1 with Example 1′ that a 2^{nd} check position 71 of the first distributed CRC interleaver in Example 1 becomes a 1^{st} check position of the first distributed CRC interleaver in Example 1′, a 3^{rd} check position 72 of the first distributed CRC interleaver in Example 1 becomes a 2^{nd} check position of the first distributed CRC interleaver in Example 1′, a 4^{th} check position 73 of the first distributed CRC interleaver in Example 1 becomes a 3^{rd} check position of the first distributed CRC interleaver in Example 1′, a 5^{th} check position 74 of the first distributed CRC interleaver in Example 1 becomes a 4^{th} check position of the first distributed CRC interleaver in Example 1′, a 1^{st} check position 70 of the first distributed CRC interleaver in Example 1 becomes a 5^{th} check position of the first distributed CRC interleaver in Example 1′, and a 6^{th} check position of the first distributed CRC interleaver in Example 1 is still a 6^{th} check position of the first distributed CRC interleaver in Example 1′. It should be noted that a message position checked at each check position also changes as the check position changes.

In this disclosure, for any CRC generator polynomial, a corresponding distributed CRC interleaver may be generated in a manner similar to the manner in the example of obtaining the first distributed CRC interleaver based on the CRC generator polynomial in step 502; or a corresponding distributed CRC interleaver may be generated in a manner similar to the manner in the example of obtaining the first distributed CRC interleaver based on the L-length CRC generator polynomial in step 402.

Example 2: L is equal to 6, K2 is equal to 70, the CRC generator polynomial is D\hat{ }6+D\hat{ }5+D\hat{ }4+D\hat{ }3+1, and values of the elements in the first distributed CRC interleaver are sequentially as follows: 1, 4, 5, 6, 9, 10, 16, 19, 20, 21, 24, 25, 31, 34, 35, 36, 39, 40, 46, 49, 50, 51, 54, 55, 61, 64, 65, 66, 69, 70, 2, 7, 11, 17, 22, 26, 32, 37, 41, 47, 52, 56, 62, 67, 71, 3, 8, 12, 18, 23, 27, 33, 38, 42, 48, 53, 57, 63, 68, 72, 13, 28, 43, 58, 73, 14, 29, 44, 59, 74, 0, 15, 30, 45, 60, and 75.

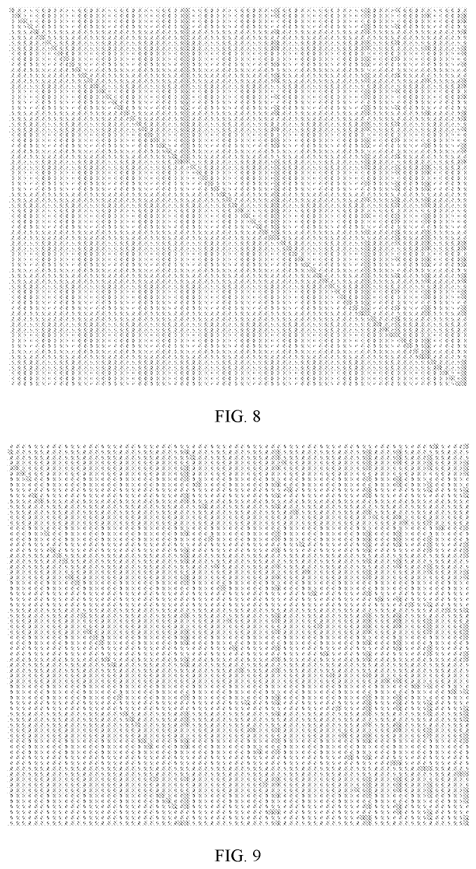

CRC interleaver is an upper triangular matrix shown in FIG. 8. FIG. 8 is an example of a DCRC encoding matrix corresponding to another first distributed CRC interleaver according to an embodiment of this disclosure. If payload bits are K=50 bits, a=a0, a1, a2, . . . , and a49, and a sequence of a obtained through DCRC encoding is a bit sequence b=b0, b1, b2, . . . , and b55 with a length of K+L=50+6=56, b=a·GDcrc. GDcrc may be a submatrix of the upper triangular matrix shown in FIG. 8, or may be a submatrix of a non-upper triangular matrix in FIG. 9. FIG. 9 is an example of a DCRC encoding matrix corresponding to another first distributed CRC interleaver according to an embodiment of this disclosure. If a non-upper triangular matrix is used, an extraction manner of a submatrix is extracting last K rows of the non-upper triangular matrix, and skipping extracting first 20 rows. If a non-upper triangular matrix is used to perform DCRC encoding, an extraction manner of a submatrix is skipping elements whose values are less than 20 in the DCRC interleaver, selecting remaining elements whose values are greater than 20 as row numbers, and extracting these rows from an upper triangular matrix to form a matrix with 50 rows and 56 columns for DCRC encoding.

Example 3: L is equal to 6, K2 is equal to 70, the CRC generator polynomial is D\hat{ }6+D\hat{ }4+D\hat{ }3+D+1, and values of the elements in the first distributed CRC interleaver are sequentially as follows: 0, 1, 2, 3, 4, 5, 7, 13, 14, 15, 20, 23, 27, 28, 30, 31, 34, 36, 37, 39, 41, 42, 43, 45, 46, 47, 48, 51, 52, 56, 58, 60, 63, 64, 65, 66, 67, 68, 70, 6, 8, 16, 21, 24, 29, 32, 35, 38, 40, 44, 49, 53, 57, 59, 61, 69, 71, 9, 17, 22, 25, 33, 50, 54, 62, 72, 10, 18, 26, 55, 73, 11, 19, 74, 12, and 75.

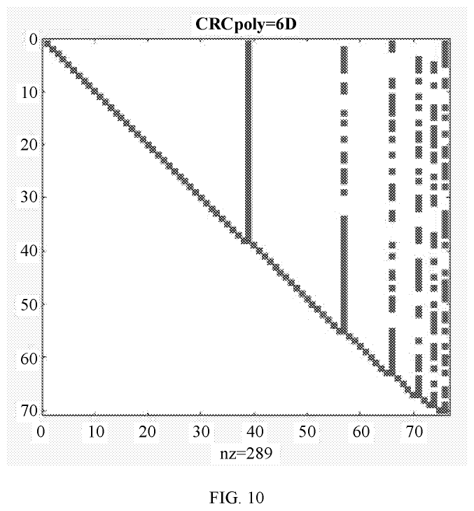

An example of the DCRC encoding matrix GDcrc corresponding to the first distributed CRC interleaver is an upper triangular matrix shown in FIG. 10. FIG. 10 is an example of a DCRC encoding matrix corresponding to another first distributed CRC interleaver according to an embodiment of this disclosure. In this specification, non-zero (nz) in the accompanying drawings represents a quantity of non-zero elements.

Example 4: L is equal to 6, K2 is equal to 70, the CRC generator polynomial is D\hat{ }6+D\hat{ }3+D\hat{ }2+D+1, and values of the elements in the first distributed CRC interleaver are sequentially as follows: 1, 2, 5, 6, 7, 10, 16, 17, 20, 21, 22, 25, 31, 32, 35, 36, 37, 40, 46, 47, 50, 51, 52, 55, 61, 62, 65, 66, 67, 70, 3, 8, 11, 18, 23, 26, 33, 38, 41, 48, 53, 56, 63, 68, 71, 4, 9, 12, 19, 24, 27, 34, 39, 42, 49, 54, 57, 64, 69, 72, 13, 28, 43, 58, 73, 14, 29, 44, 59, 74, 0, 15, 30, 45, 60, and 75.

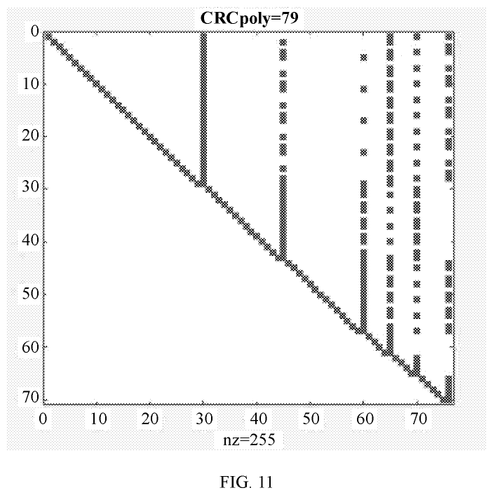

An example of the DCRC encoding matrix GDcrc corresponding to the first distributed CRC interleaver is an upper triangular matrix shown in FIG. 11. FIG. 11 is an example of a DCRC encoding matrix corresponding to another first distributed CRC interleaver according to an embodiment of this disclosure.

Example 5: L is equal to 6, K2 is equal to 70, the CRC generator polynomial is D\hat{ }6+D\hat{ }5+D\hat{ }2+1, and values of the elements in the first distributed CRC interleaver are sequentially as follows: 0, 1, 2, 4, 5, 6, 7, 13, 15, 17, 18, 21, 22, 23, 25, 26, 27, 28, 34, 36, 38, 39, 42, 43, 44, 46, 47, 48, 49, 55, 57, 59, 60, 63, 64, 65, 67, 68, 69, 70, 3, 8, 14, 16, 19, 24, 29, 35, 37, 40, 45, 50, 56, 58, 61, 66, 71, 9, 20, 30, 41, 51, 62, 72, 10, 31, 52, 73, 11, 32, 53, 74, 12, 33, 54, and 75.

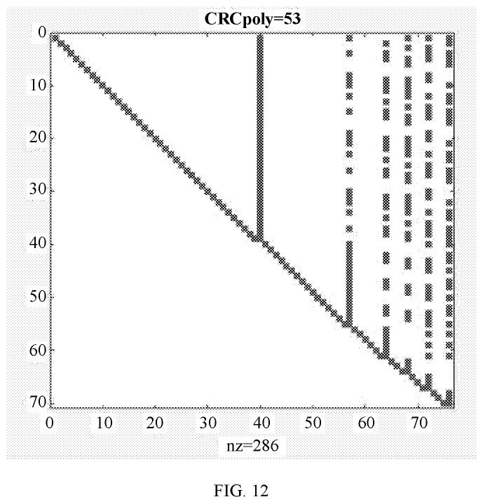

An example of the DCRC encoding matrix GDcrc corresponding to the first distributed CRC interleaver is an upper triangular matrix shown in FIG. 12. FIG. 12 is an example of a DCRC encoding matrix corresponding to another first distributed CRC interleaver according to an embodiment of this disclosure.

Example 6: L is equal to 6, K2 is equal to 70, the CRC generator polynomial is D\hat{ }6+D\hat{ }5+D\hat{ }4+D\hat{ }2+1, and values of the elements in the first distributed CRC interleaver are sequentially as follows: 0, 1, 4, 6, 7, 13, 15, 18, 21, 22, 25, 27, 28, 34, 36, 39, 42, 43, 46, 48, 49, 55, 57, 60, 63, 64, 67, 69, 70, 2, 5, 8, 14, 16, 19, 23, 26, 29, 35, 37, 40, 44, 47, 50, 56, 58, 61, 65, 68, 71, 3, 9, 17, 20, 24, 30, 38, 41, 45, 51, 59, 62, 66, 72, 10, 31, 52, 73, 11, 32, 53, 74, 12, 33, 54, and 75.

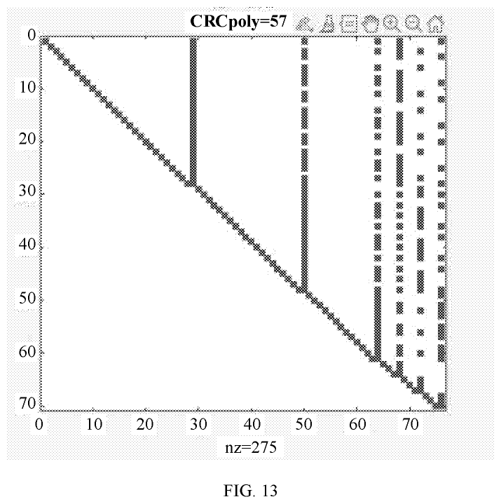

An example of the DCRC encoding matrix GDcrc corresponding to the first distributed CRC interleaver is an upper triangular matrix shown in FIG. 13. FIG. 13 is an example of a DCRC encoding matrix corresponding to another first distributed CRC interleaver according to an embodiment of this disclosure.

Example 7: L is equal to 6, K2 is equal to 70, the CRC generator polynomial is D\hat{ }6+D\hat{ }3+D\hat{ }2+1, and values of the elements in the first distributed CRC interleaver are sequentially as follows: 0, 4, 5, 8, 14, 16, 17, 18, 20, 21, 23, 25, 28, 29, 30, 31, 35, 36, 39, 45, 47, 48, 49, 51, 52, 54, 56, 59, 60, 61, 62, 66, 67, 70, 1, 6, 9, 15, 19, 22, 24, 26, 32, 37, 40, 46, 50, 53, 55, 57, 63, 68, 71, 2, 7, 10, 27, 33, 38, 41, 58, 64, 69, 72, 3, 11, 34, 42, 65, 73, 12, 43, 74, 13, 44, and 75.

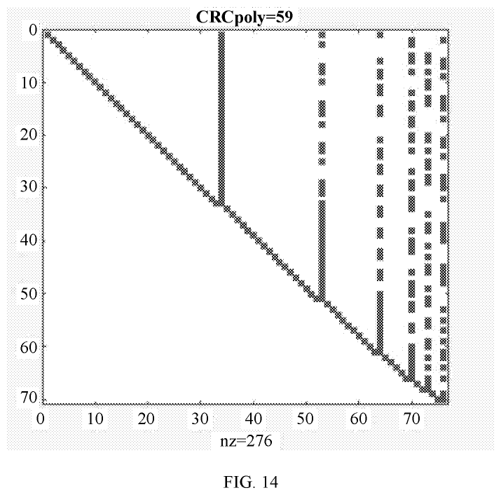

An example of the DCRC encoding matrix GDcrc corresponding to the first distributed CRC interleaver is an upper triangular matrix shown in FIG. 14. FIG. 14 is an example of a DCRC encoding matrix corresponding to another first distributed CRC interleaver according to an embodiment of this disclosure.

Example 8: L is equal to 6, K2 is equal to 70, the CRC generator polynomial is D\hat{ }6+D\hat{ }5+D\hat{ }3+D\hat{ }2+1, and values of the elements in the first distributed CRC interleaver are sequentially as follows: 0, 5, 6, 7, 13, 15, 16, 17, 18, 19, 20, 23, 25, 27, 31, 32, 35, 36, 37, 38, 40, 41, 42, 44, 46, 47, 49, 52, 53, 55, 56, 60, 63, 68, 69, 70, 1, 8, 14, 21, 24, 26, 28, 33, 39, 43, 45, 48, 50, 54, 57, 61, 64, 71, 2, 9, 22, 29, 34, 51, 58, 62, 65, 72, 3, 10, 30, 59, 66, 73, 4, 11, 67, 74, 12, and 75.

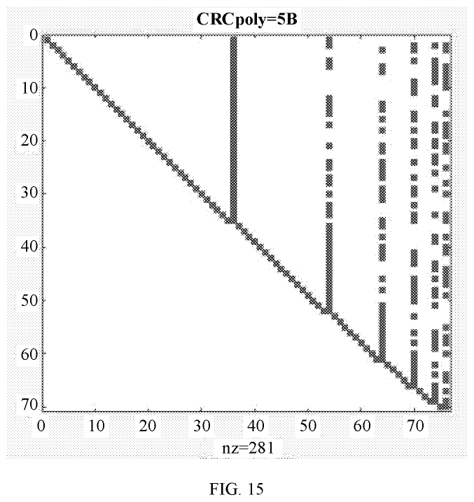

An example of the DCRC encoding matrix GDcrc corresponding to the first distributed CRC interleaver is an upper triangular matrix shown in FIG. 15. FIG. 15 is an example of a DCRC encoding matrix corresponding to another first distributed CRC interleaver according to an embodiment of this disclosure.

Example 9: L is equal to 6, K2 is equal to 70, the CRC generator polynomial is D\hat{ }6+D\hat{ }5+D\hat{ }4+D\hat{ }3+D\hat{ }2+1, and values of the elements in the first distributed CRC interleaver are sequentially as follows: 0, 2, 5, 9, 10, 16, 18, 19, 21, 22, 23, 26, 27, 28, 29, 30, 32, 35, 39, 40, 46, 48, 49, 51, 52, 53, 56, 57, 58, 59, 60, 62, 65, 69, 70, 1, 3, 6, 11, 17, 20, 24, 31, 33, 36, 41, 47, 50, 54, 61, 63, 66, 71, 4, 7, 12, 25, 34, 37, 42, 55, 64, 67, 72, 8, 13, 38, 43, 68, 73, 14, 44, 74, 15, 45, and 75.

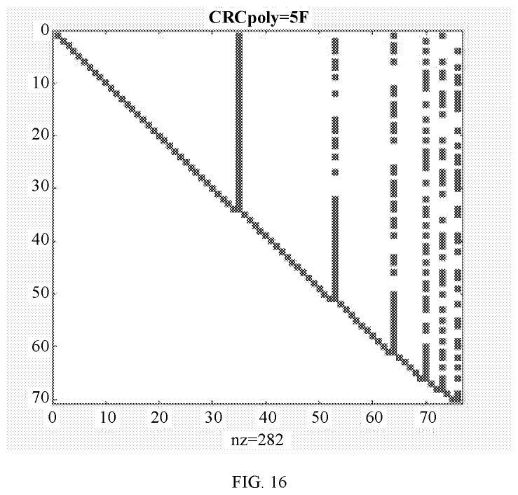

An example of the DCRC encoding matrix GDcrc corresponding to the first distributed CRC interleaver is an upper triangular matrix shown in FIG. 16. FIG. 16 is an example of a DCRC encoding matrix corresponding to another first distributed CRC interleaver according to an embodiment of this disclosure.

Example 10: L is equal to 6, K2 is equal to 70, the CRC generator polynomial is D\hat{ }6+D\hat{ }5+D\hat{ }4+D\hat{ }3+D+1, and values of the elements in the first distributed CRC interleaver are sequentially as follows: 1, 2, 4, 7, 8, 14, 15, 16, 19, 23, 25, 27, 28, 29, 30, 32, 33, 35, 38, 39, 45, 46, 47, 50, 54, 56, 58, 59, 60, 61, 63, 64, 66, 69, 70, 0, 3, 5, 9, 17, 20, 24, 26, 31, 34, 36, 40, 48, 51, 55, 57, 62, 65, 67, 71, 6, 10, 18, 21, 37, 41, 49, 52, 68, 72, 11, 22, 42, 53, 73, 12, 43, 74, 13, 44, and 75.

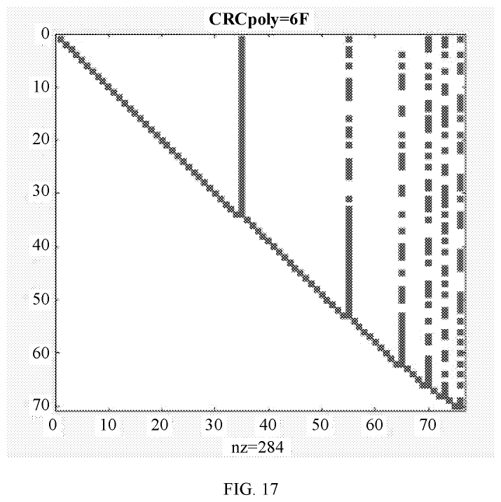

An example of the DCRC encoding matrix GDcrc corresponding to the first distributed CRC interleaver is an upper triangular matrix shown in FIG. 17. FIG. 17 is an example of a DCRC encoding matrix corresponding to another first distributed CRC interleaver according to an embodiment of this disclosure.

Example 11: L is equal to 6, K2 is equal to 70, the CRC generator polynomial is D\hat{ }6+D\hat{ }4+D\hat{ }2+D+1, and values of the elements in the first distributed CRC interleaver are sequentially as follows: 2, 5, 7, 13, 14, 16, 19, 20, 23, 26, 28, 34, 35, 37, 40, 41, 44, 47, 49, 55, 56, 58, 61, 62, 65, 68, 70, 0, 3, 6, 8, 15, 17, 21, 24, 27, 29, 36, 38, 42, 45, 48, 50, 57, 59, 63, 66, 69, 71, 1, 4, 9, 18, 22, 25, 30, 39, 43, 46, 51, 60, 64, 67, 72, 10, 31, 52, 73, 11, 32, 53, 74, 12, 33, 54, and 75.

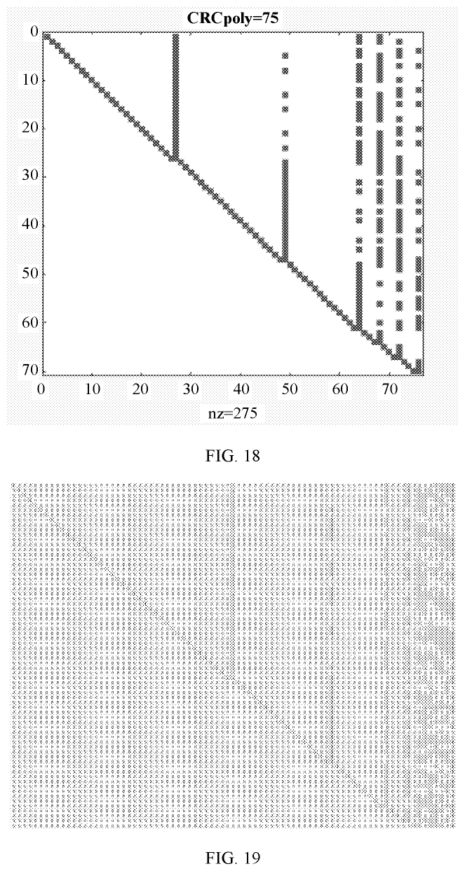

An example of the DCRC encoding matrix GDcrc corresponding to the first distributed CRC interleaver is an upper triangular matrix shown in FIG. 18. FIG. 18 is an example of a DCRC encoding matrix corresponding to another first distributed CRC interleaver according to an embodiment of this disclosure.

Example 12: L is equal to 11, K2 is equal to 70, the CRC generator polynomial is D\hat{ }11+D\hat{ }10+D\hat{ }9+D\hat{ }5+1, and values of the elements in the first distributed CRC interleaver are sequentially as follows: 0, 1, 2, 3, 4, 6, 7, 10, 13, 15, 19, 21, 22, 23, 24, 25, 27, 30, 33, 34, 35, 37, 41, 44, 46, 47, 48, 49, 50, 55, 57, 58, 59, 60, 61, 62, 63, 66, 67, 69, 70, 5, 8, 11, 14, 16, 20, 26, 28, 31, 36, 38, 42, 45, 51, 56, 64, 68, 71, 9, 12, 17, 29, 32, 39, 43, 52, 65, 72, 18, 40, 53, 73, 54, 74, 75, 76, 77, 78, 79, and 80.

The first distributed CRC interleaver in Example 12 is obtained based on D\hat{ }11+D\hat{ }10+D\hat{ }9+D\hat{ }5+1. A manner of obtaining the first distributed CRC interleaver in Example 12 based on D\hat{ }11+D\hat{ }10+D\hat{ }9+D\hat{ }5+1 may be similar to the manner in the example of obtaining the first distributed CRC interleaver based on the CRC generator polynomial in step 502. Details are not described herein again.

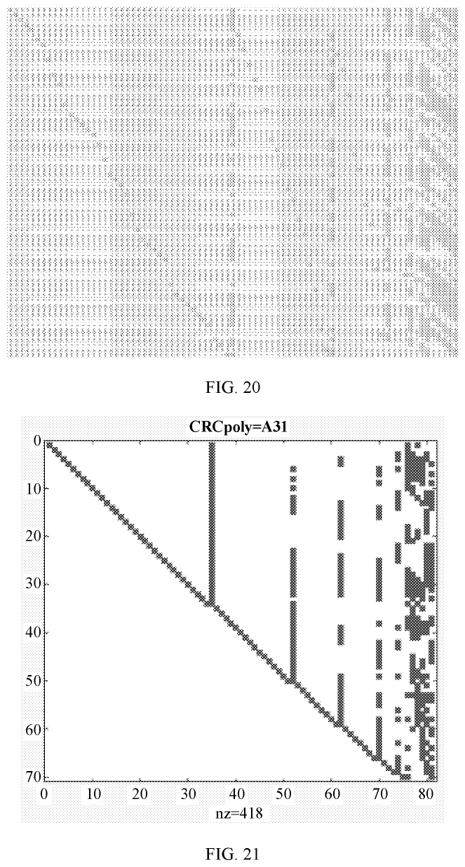

A DCRC encoding matrix GDcrc corresponding to the first distributed CRC interleaver may be in the following two forms: one form is an upper triangular GDcrc1. To be specific, DCRC interleaving is performed on both the K rows and the (K+L) columns of Gcrc, where an interleaver used for interleaving of the K rows is an interleaver including K elements whose values are less than K and that are read from the DCRC interleaver in a natural order in a nested manner, and an interleaver used for interleaving of the (K+L) columns is the foregoing (K+L)-length DCRC interleaver. The other form of the DCRC encoding matrix is also a matrix with K rows and (K+L) columns, but is not the upper triangle, that is, GDcrc2, where the matrix is generated by performing interleaving only on the (K+L) columns of Gcrc, not on the K rows of the matrix. If payload bits are K=70 bits, a=a0, a1, a2, . . . , and a69, and a sequence obtained through DCRC encoding is a bit sequence b=b0, b1, b2, . . . , and b80 with a length of K+L=70+11=81, b=a·GDcrc1 or b=a·GDcrc2. GDcrc1 is an upper triangular matrix shown in FIG. 19. FIG. 19 is an example of a DCRC encoding matrix corresponding to a first distributed CRC interleaver according to an embodiment of this disclosure. GDcrc2 is a non-upper triangular matrix shown in FIG. 20, where interleaving is only performed on columns of Gcrc. FIG. 20 is an example of a DCRC encoding matrix corresponding to another first distributed CRC interleaver according to an embodiment of this disclosure. An advantage of GDcrc2 is that it is more convenient to read the DCRC encoding matrix in a nested manner. For a payload whose K is less than 70, first (70−K) rows of the matrix need to be skipped, and DCRC encoding is performed by using only last K rows of the matrix.

Example 12′: L is equal to 11, K2 is equal to 70, the CRC generator polynomial is D\hat{ }11+D\hat{ }10+D\hat{ }9+D\hat{ }5+1, and values of the elements in the first distributed CRC interleaver are sequentially as follows: 1, 2, 5, 8, 10, 14, 16, 17, 18, 19, 20, 22, 25, 28, 29, 30, 32, 36, 39, 41, 42, 43, 44, 45, 50, 52, 53, 54, 55, 56, 57, 58, 61, 62, 64, 65, 76, 0, 3, 4, 9, 11, 12, 13, 23, 24, 31, 33, 35, 38, 48, 49, 59, 60, 63, 66, 72, 6, 15, 21, 26, 37, 40, 46, 51, 77, 34, 67, 73, 7, 27, 47, 78, 68, 74, 79, 69, 70, 71, 75, and 80.

The first distributed CRC interleaver in Example 12′ is obtained based on D\hat{ }11+D\hat{ }10+D\hat{ }9+D\hat{ }5+1. A manner of obtaining the first distributed CRC interleaver in Example 12′ based on D\hat{ }11+D\hat{ }10+D\hat{ }9+D\hat{ }5+1 may be similar to the manner in the example of obtaining the first distributed CRC interleaver based on the L-length CRC generator polynomial in step 402. Details are not described herein again. The first distributed CRC interleaver in Example 12 and the first distributed CRC interleaver in Example 12′ are obtained based on a same CRC generator polynomial, and a difference lies in that: when the first distributed CRC interleaver in Example 12 is obtained based on D\hat{ }11+D\hat{ }10+D\hat{ }9+D\hat{ }5+1, positions of message bits associated with check columns and positions of the check columns are packed as a whole in a sequence of the positions of the check columns. When the first distributed CRC interleaver in Example 12′ is obtained based on D\hat{ }11+D\hat{ }10+D\hat{ }9+D\hat{ }5+1, positions of message bits associated with check columns and positions of the check columns are packed as a whole in ascending order of largest values (that is, positions of last message bits checked in the check columns) in element sequences corresponding to the check columns. It can be learned by comparing Example 12 with Example 12′ that a 7^{th} check position 76 of the first distributed CRC interleaver in Example 12 becomes a 1^{st} check position of the first distributed CRC interleaver in Example 12′, a 3^{rd} check position 72 of the first distributed CRC interleaver in Example 12 becomes a 2^{nd} check position of the first distributed CRC interleaver in Example 12′, an 8^{th} check position 77 of the first distributed CRC interleaver in Example 12 becomes a 3^{rd} check position of the first distributed CRC interleaver in Example 12′, a 4^{th} check position 73 of the first distributed CRC interleaver in Example 12 is still a 4^{th} check position of the first distributed CRC interleaver in Example 12′, a 9^{th} check position 78 of the first distributed CRC interleaver in Example 12 becomes a 5^{th} check position of the first distributed CRC interleaver in Example 12′, a 5^{th} check position 74 of the first distributed CRC interleaver in Example 12 becomes a 6^{th} check position of the first distributed CRC interleaver in Example 12′, a 10^{th} check position 79 of the first distributed CRC interleaver in Example 12 becomes a 7^{th} check position of the first distributed CRC interleaver in Example 12′, a 1^{st} check position 70 of the first distributed CRC interleaver in Example 12 becomes an 8^{th} check position of the first distributed CRC interleaver in Example 12′, a 2^{nd} check position 71 of the first distributed CRC interleaver in Example 12 becomes a 9^{th} check position of the first distributed CRC interleaver in Example 12′, a 6^{th} check position 75 of the first distributed CRC interleaver in Example 12 becomes a 10^{th} check position of the first distributed CRC interleaver in Example 12′, an 11^{th} check position 80 of the first distributed CRC interleaver in Example 12 is still an 11^{th} check position of the first distributed CRC interleaver in Example 12′, and a message position checked at each check position also changes as the check position changes.

Example 13: L is equal to 11, K2 is equal to 70, the CRC generator polynomial is D\hat{ }11+D\hat{ }7+D\hat{ }6+D\hat{ }2+1, and values of the elements in the first distributed CRC interleaver are sequentially as follows: 1, 5, 11, 13, 15, 16, 19, 20, 23, 24, 29, 30, 31, 32, 33, 35, 37, 39, 41, 43, 47, 52, 53, 54, 55, 56, 57, 58, 59, 60, 61, 62, 65, 66, 70, 2, 6, 12, 14, 17, 21, 25, 34, 36, 38, 40, 42, 44, 48, 63, 67, 71, 3, 7, 18, 22, 26, 45, 49, 64, 68, 72, 0, 4, 8, 27, 46, 50, 69, 73, 9, 28, 51, 74, 10, 75, 76, 77, 78, 79, and 80.

An example of the DCRC encoding matrix GDcrc corresponding to the first distributed CRC interleaver is an upper triangular matrix shown in FIG. 21. FIG. 21 is an example of a DCRC encoding matrix corresponding to another first distributed CRC interleaver according to an embodiment of this disclosure.

Example 14: L is equal to 11, K2 is equal to 70, the CRC generator polynomial is D\hat{ }11+D\hat{ }10+D\hat{ }9+D\hat{ }6+D\hat{ }4+D\hat{ }2+1, and values of the elements in the first distributed CRC interleaver are sequentially as follows: 0, 1, 5, 6, 9, 10, 12, 13, 14, 16, 19, 21, 22, 23, 24, 25, 26, 29, 34, 36, 37, 38, 41, 43, 47, 49, 50, 51, 52, 54, 61, 63, 64, 65, 66, 67, 69, 70, 2, 7, 11, 15, 17, 20, 27, 30, 35, 39, 42, 44, 48, 53, 55, 62, 68, 71, 3, 8, 18, 28, 31, 40, 45, 56, 72, 4, 32, 46, 57, 73, 33, 58, 74, 59, 75, 60, 76, 77, 78, 79, and 80.

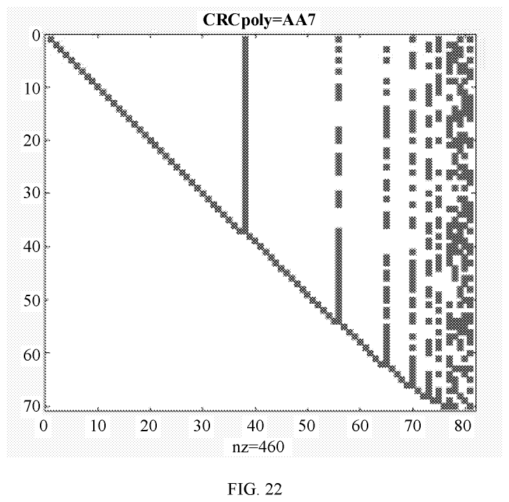

An example of the DCRC encoding matrix GDcrc corresponding to the first distributed CRC interleaver is an upper triangular matrix shown in FIG. 22. FIG. 22 is an example of a DCRC encoding matrix corresponding to another first distributed CRC interleaver according to an embodiment of this disclosure.

Example 15: L is equal to 11, K2 is equal to 70, the CRC generator polynomial is D\hat{ }11+D\hat{ }10+D\hat{ }9+D\hat{ }7+D\hat{ }5+D+1, and values of the elements in the first distributed CRC interleaver are sequentially as follows: 0, 5, 7, 8, 11, 12, 16, 18, 19, 21, 22, 24, 25, 27, 30, 34, 38, 39, 46, 50, 53, 54, 55, 58, 59, 63, 64, 67, 69, 70, 1, 6, 9, 13, 17, 20, 23, 26, 28, 31, 35, 40, 47, 51, 56, 60, 65, 68, 71, 2, 10, 14, 29, 32, 36, 41, 48, 52, 57, 61, 66, 72, 3, 15, 33, 37, 42, 49, 62, 73, 4, 43, 74, 44, 75, 45, 76, 77, 78, 79, and 80.

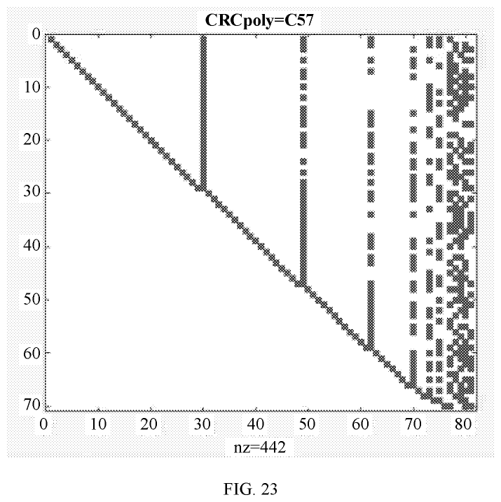

An example of the DCRC encoding matrix GDcrc corresponding to the first distributed CRC interleaver is an upper triangular matrix shown in FIG. 23. FIG. 23 is an example of a DCRC encoding matrix corresponding to another first distributed CRC interleaver according to an embodiment of this disclosure.

Example 16: L is equal to 11, K2 is equal to 70, the CRC generator polynomial is D\hat{ }11+D\hat{ }9+D\hat{ }8+D\hat{ }6+D\hat{ }5+D+1, and values of the elements in the first distributed CRC interleaver are sequentially as follows: 0, 10, 15, 18, 20, 21, 22, 23, 24, 27, 29, 31, 32, 35, 36, 38, 41, 42, 44, 46, 47, 49, 53, 54, 55, 58, 59, 63, 64, 65, 66, 67, 68, 70, 1, 11, 16, 19, 25, 28, 30, 33, 37, 39, 43, 45, 48, 50, 56, 60, 69, 71, 2, 12, 17, 26, 34, 40, 51, 57, 61, 72, 3, 13, 52, 62, 73, 4, 14, 74, 5, 75, 6, 76, 7, 77, 8, 78, 9, 79, and 80.

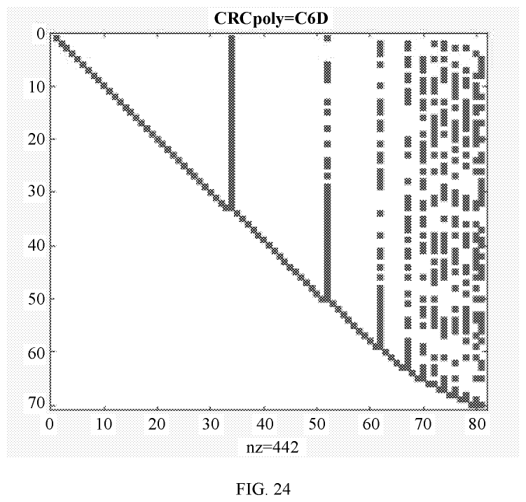

An example of the DCRC encoding matrix GDcrc corresponding to the first distributed CRC interleaver is an upper triangular matrix shown in FIG. 24. FIG. 24 is an example of a DCRC encoding matrix corresponding to another first distributed CRC interleaver according to an embodiment of this disclosure.

Example 17: L is equal to 11, K2 is equal to 70, the CRC generator polynomial is D\hat{ }11+D\hat{ }10+D\hat{ }9+D\hat{ }8+D\hat{ }7+D\hat{ }5+D\hat{ }4+D+1, and values of the elements in the first distributed CRC interleaver are sequentially as follows: 1, 2, 4, 5, 8, 9, 11, 13, 17, 18, 20, 24, 27, 28, 30, 32, 33, 36, 39, 40, 41, 42, 43, 44, 47, 49, 52, 53, 54, 55, 61, 62, 63, 65, 69, 70, 3, 6, 10, 12, 14, 19, 21, 25, 29, 31, 34, 37, 45, 48, 50, 56, 64, 66, 71, 7, 15, 22, 26, 35, 38, 46, 51, 57, 67, 72, 0, 16, 23, 58, 68, 73, 59, 74, 60, 75, 76, 77, 78, 79, and 80.

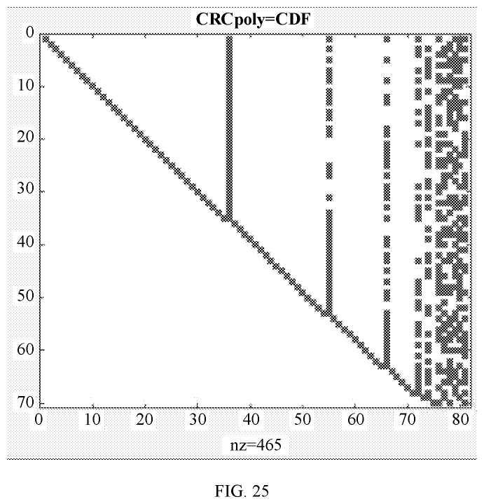

An example of the DCRC encoding matrix GDcrc corresponding to the first distributed CRC interleaver is an upper triangular matrix shown in FIG. 25. FIG. 25 is an example of a DCRC encoding matrix corresponding to another first distributed CRC interleaver according to an embodiment of this disclosure.

Example 18: L is equal to 11, K2 is equal to 70, the CRC generator polynomial is D\hat{ }11+D\hat{ }10+D\hat{ }3+D+1, and values of the elements in the first distributed CRC interleaver are sequentially as follows: 2, 3, 4, 5, 9, 16, 17, 18, 19, 20, 22, 25, 28, 29, 30, 31, 32, 33, 38, 39, 40, 42, 44, 47, 50, 52, 53, 56, 58, 60, 61, 63, 64, 65, 66, 67, 68, 69, 70, 0, 6, 10, 21, 23, 26, 34, 41, 43, 45, 48, 51, 54, 57, 59, 62, 71, 1, 7, 11, 24, 27, 35, 46, 49, 55, 72, 8, 12, 36, 73, 13, 37, 74, 14, 75, 15, 76, 77, 78, 79, and 80.

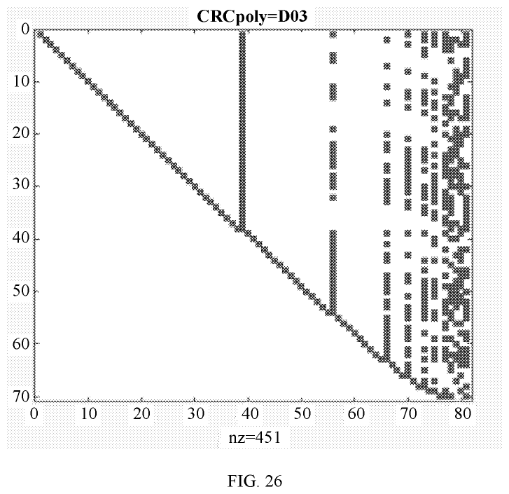

An example of the DCRC encoding matrix GDcrc corresponding to the first distributed CRC interleaver is an upper triangular matrix shown in FIG. 26. FIG. 26 is an example of a DCRC encoding matrix corresponding to another first distributed CRC interleaver according to an embodiment of this disclosure.

Example 19: L is equal to 11, K2 is equal to 70, the CRC generator polynomial is D\hat{ }11+D\hat{ }5+D\hat{ }3+D+1, and values of the elements in the first distributed CRC interleaver are sequentially as follows: 2, 5, 13, 14, 15, 16, 20, 23, 27, 30, 32, 34, 35, 36, 37, 38, 39, 40, 43, 47, 48, 52, 54, 58, 59, 60, 62, 64, 70, 0, 3, 6, 17, 21, 24, 28, 31, 33, 41, 44, 49, 53, 55, 61, 63, 65, 71, 1, 4, 7, 18, 22, 25, 29, 42, 45, 50, 56, 66, 72, 8, 19, 26, 46, 51, 57, 67, 73, 9, 68, 74, 10, 69, 75, 11, 76, 12, 77, 78, 79, and 80.

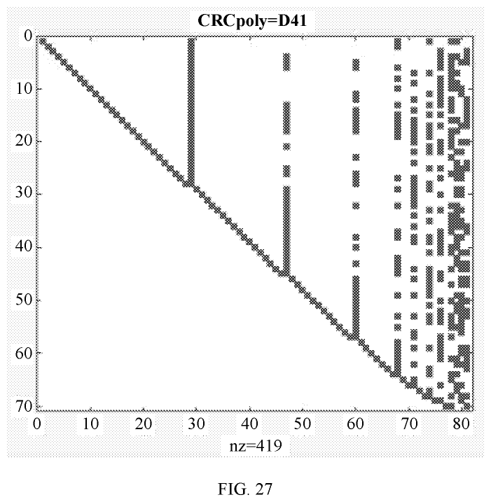

An example of the DCRC encoding matrix GDcrc corresponding to the first distributed CRC interleaver is an upper triangular matrix shown in FIG. 27. FIG. 27 is an example of a DCRC encoding matrix corresponding to another first distributed CRC interleaver according to an embodiment of this disclosure.

Example 20: L is equal to 11, K2 is equal to 70, the CRC generator polynomial is D\hat{ }11+D\hat{ }10+D\hat{ }9+D\hat{ }8+D\hat{ }6+D\hat{ }5+D\hat{ }3+D+1, and values of the elements in the first distributed CRC interleaver are sequentially as follows: 0, 1, 3, 4, 5, 8, 9, 10, 13, 22, 24, 28, 33, 34, 39, 41, 46, 47, 49, 53, 54, 56, 57, 60, 61, 62, 63, 64, 66, 69, 70, 2, 6, 11, 14, 23, 25, 29, 35, 40, 42, 48, 50, 55, 58, 65, 67, 71, 7, 12, 15, 26, 30, 36, 43, 51, 59, 68, 72, 16, 27, 31, 37, 44, 52, 73, 17, 32, 38, 45, 74, 18, 75, 19, 76, 20, 77, 21, 78, 79, and 80.

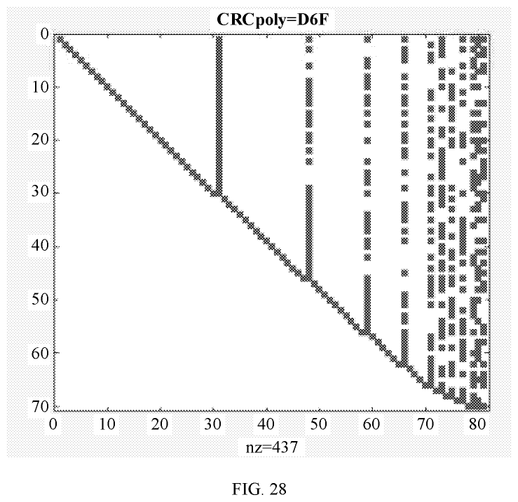

An example of the DCRC encoding matrix GDcrc corresponding to the first distributed CRC interleaver is an upper triangular matrix shown in FIG. 28. FIG. 28 is an example of a DCRC encoding matrix corresponding to another first distributed CRC interleaver according to an embodiment of this disclosure.

Example 21: L is equal to 11, K2 is equal to 70, the CRC generator polynomial is D\hat{ }11+D\hat{ }10+D\hat{ }8+D\hat{ }7+D\hat{ }6+D\hat{ }5+D\hat{ }3+D+1, and values of the elements in the first distributed CRC interleaver are sequentially as follows: 0, 3, 5, 6, 7, 8, 11, 13, 15, 17, 19, 21, 22, 26, 27, 30, 31, 32, 33, 35, 36, 41, 42, 43, 47, 49, 53, 61, 62, 65, 68, 69, 70, 1, 4, 9, 12, 14, 16, 18, 20, 23, 28, 34, 37, 44, 48, 50, 54, 63, 66, 71, 2, 10, 24, 29, 38, 45, 51, 55, 64, 67, 72, 25, 39, 46, 52, 56, 73, 40, 57, 74, 58, 75, 59, 76, 60, 77, 78, 79, and 80.

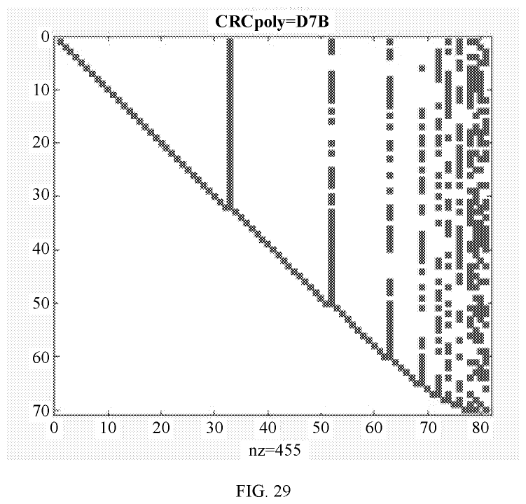

An example of the DCRC encoding matrix GDcrc corresponding to the first distributed CRC interleaver is an upper triangular matrix shown in FIG. 29. FIG. 29 is an example of a DCRC encoding matrix corresponding to another first distributed CRC interleaver according to an embodiment of this disclosure.

Example 22: L is equal to 11, K2 is equal to 70, the CRC generator polynomial is D\hat{ }11+D\hat{ }9+D\hat{ }7+D\hat{ }6+D\hat{ }5+D\hat{ }4+D\hat{ }3+D+1, and values of the elements in the first distributed CRC interleaver are sequentially as follows: 1, 4, 6, 9, 12, 14, 15, 16, 23, 28, 30, 34, 35, 37, 38, 39, 41, 42, 43, 45, 46, 47, 48, 51, 52, 53, 56, 60, 61, 63, 65, 68, 70, 2, 5, 7, 10, 13, 17, 24, 29, 31, 36, 40, 44, 49, 54, 57, 62, 64, 66, 69, 71, 0, 3, 8, 11, 18, 25, 32, 50, 55, 58, 67, 72, 19, 26, 33, 59, 73, 20, 27, 74, 21, 75, 22, 76, 77, 78, 79, and 80.

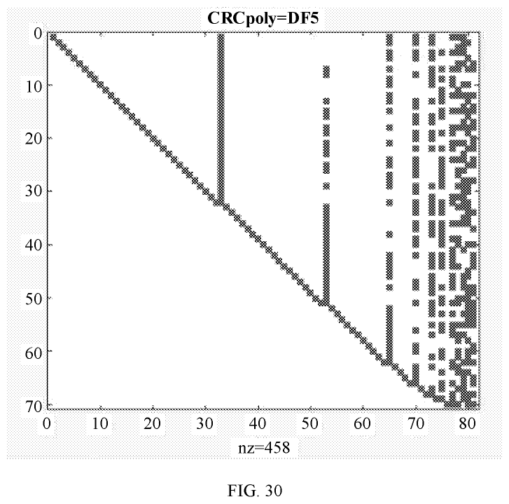

An example of the DCRC encoding matrix GDcrc corresponding to the first distributed CRC interleaver is an upper triangular matrix shown in FIG. 30. FIG. 30 is an example of a DCRC encoding matrix corresponding to another first distributed CRC interleaver according to an embodiment of this disclosure.

Example 23: L is equal to 11, K2 is equal to 70, the CRC generator polynomial is D\hat{ }11+D\hat{ }10+D\hat{ }9+D\hat{ }7+D\hat{ }6+D\hat{ }3+D\hat{ }2+D+1, and values of the elements in the first distributed CRC interleaver are sequentially as follows: 2, 3, 6, 8, 9, 11, 12, 13, 14, 21, 24, 26, 27, 28, 29, 30, 31, 32, 34, 36, 37, 38, 39, 40, 41, 47, 48, 49, 53, 54, 57, 61, 65, 67, 69, 70, 0, 4, 7, 10, 15, 22, 25, 33, 35, 42, 50, 55, 58, 62, 66, 68, 71, 1, 5, 16, 23, 43, 51, 56, 59, 63, 72, 17, 44, 52, 60, 64, 73, 18, 45, 74, 19, 46, 75, 20, 76, 77, 78, 79, and 80.

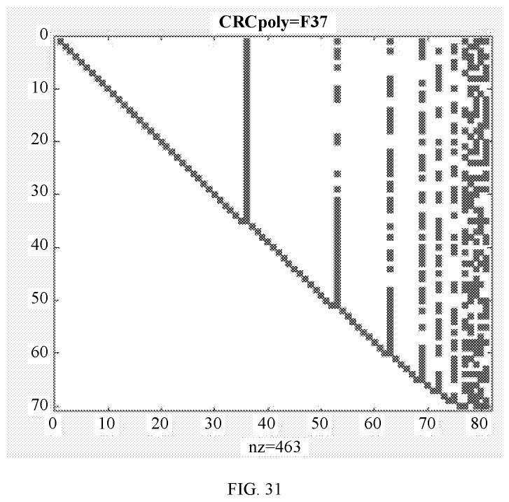

An example of the DCRC encoding matrix GDcrc corresponding to the first distributed CRC interleaver is an upper triangular matrix shown in FIG. 31. FIG. 31 is an example of a DCRC encoding matrix corresponding to another first distributed CRC interleaver according to an embodiment of this disclosure.

Example 24: L is equal to 11, K2 is equal to 70, the CRC generator polynomial is D\hat{ }11+D\hat{ }8+D\hat{ }6+D\hat{ }5+D\hat{ }4+D\hat{ }3+D\hat{ }2+D+1, and values of the elements in the first distributed CRC interleaver are sequentially as follows: 2, 3, 4, 5, 6, 7, 12, 14, 16, 20, 22, 23, 26, 31, 34, 37, 39, 40, 41, 44, 46, 49, 51, 52, 53, 54, 58, 62, 63, 65, 67, 70, 0, 8, 13, 15, 17, 21, 24, 27, 32, 35, 38, 42, 45, 47, 50, 55, 59, 64, 66, 68, 71, 1, 9, 18, 25, 28, 33, 36, 43, 48, 56, 60, 69, 72, 10, 19, 29, 57, 61, 73, 11, 30, 74, 75, 76, 77, 78, 79, and 80.

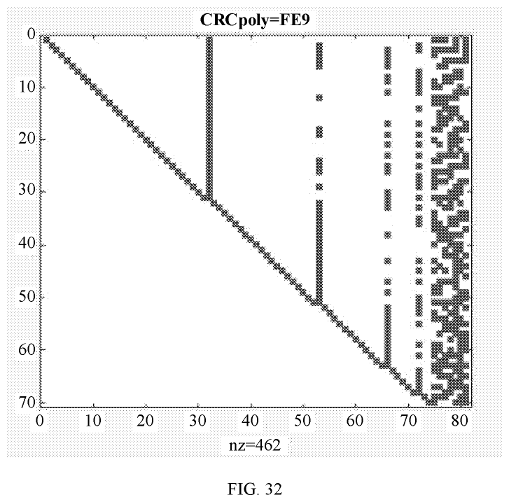

An example of the DCRC encoding matrix GDcrc corresponding to the first distributed CRC interleaver is an upper triangular matrix shown in FIG. 32. FIG. 32 is an example of a DCRC encoding matrix corresponding to another first distributed CRC interleaver according to an embodiment of this disclosure.

Example 25: L is equal to 16, K2 is equal to 100, the CRC generator polynomial is D\hat{ }16+D\hat{ }12+D\hat{ }5+1, and values of the elements in the first distributed CRC interleaver are sequentially as follows: 2, 4, 5, 12, 14, 16, 18, 19, 20, 23, 25, 26, 28, 30, 33, 34, 35, 36, 37, 42, 44, 45, 48, 49, 51, 52, 58, 65, 67, 68, 72, 73, 74, 78, 80, 81, 88, 89, 92, 96, 100, 3, 6, 13, 15, 17, 21, 24, 27, 29, 31, 38, 43, 46, 50, 53, 59, 66, 69, 75, 79, 82, 90, 93, 97, 101, 7, 22, 32, 39, 47, 54, 60, 70, 76, 83, 91, 94, 98, 102, 8, 40, 55, 61, 71, 77, 84, 95, 99, 103, 0, 9, 41, 56, 62, 85, 104, 1, 10, 57, 63, 86, 105, 11, 64, 87, 106, 107, 108, 109, 110, 111, 112, 113, 114, and 115.

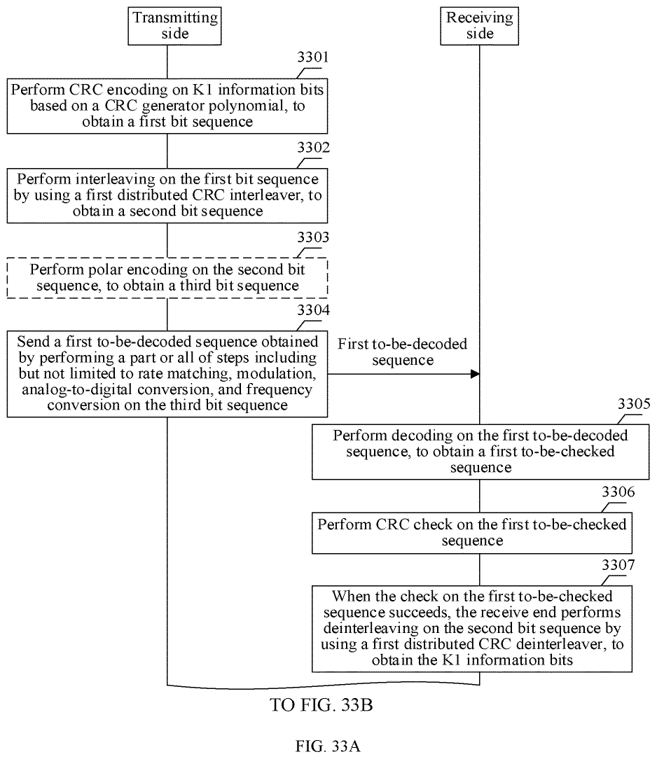

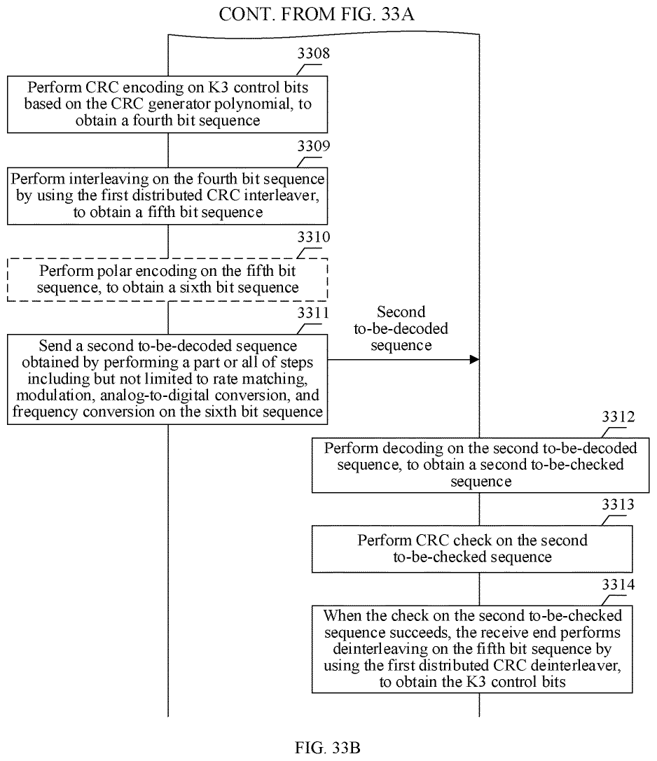

In a possible implementation, a low-power device may use only one channel coding scheme. For example, a data channel, a broadcast channel, and a control channel of a passive IoT all use NR control channel encoding, that is, the channel coding scheme provided in this disclosure. However, a maximum mother code length and a minimum mother code length are changed to further reduce power consumption. For example, the minimum mother code length Nm may be less than 32, for example, Nm=16; and the maximum mother code length Nmax may be reduced to the following values {32, 64, 128, 256}. FIG. 33A and FIG. 33B each are a flowchart of another encoding method according to an embodiment of this disclosure. A method procedure in FIG. 33A and FIG. 33B is a possible implementation of the method described in FIG. 4. The method procedure in FIG. 33A and FIG. 33B may be applied to low-power scenarios. As shown in FIG. 33A and FIG. 33B, the method includes the following steps.

3301: A transmitting side performs CRC encoding on K1 information bits based on a CRC generator polynomial, to obtain a first bit sequence.

3302: The transmitting side performs interleaving on the first bit sequence by using a first distributed CRC interleaver, to obtain a second bit sequence.

3303: The transmitting side performs polar encoding on the second bit sequence, to obtain a third bit sequence.

For example, a minimum mother code length Nm may be less than 32, for example, Nm=16; and a maximum mother code length Nmax may be reduced to the following values {32, 64, 128, 256}.

3304: The transmitting side sends a first to-be-decoded sequence obtained by performing a part or all of steps including but not limited to rate matching, modulation, analog-to-digital conversion, and frequency conversion on the third bit sequence.

Correspondingly, the receiving side receives, from the transmitting side, a signal that carries the first to-be-decoded sequence.

In a possible implementation, in step 3304, the obtained first to-be-decoded sequence sent by the transmitting side may be a sent data signal, that is, a data signal used by the receiving side to obtain the K1 information bits through decoding. Step 3301 to step 3304 include a process in which the transmitting side performs channel encoding on the K1 information bits that need to be sent through a data channel.

In a possible implementation, in step 3304, the obtained first to-be-decoded sequence sent by the transmitting side may be a sent broadcast signal, that is, a broadcast signal used by the receiving side to obtain the K1 information bits through decoding. Step 3301 to step 3304 include a process in which the transmitting side performs channel encoding on the K1 information bits that need to be sent through a broadcast channel.

3305: The receiving side performs decoding on the first to-be-decoded sequence, to obtain a first to-be-checked sequence.

The receiving side may obtain the first to-be-decoded sequence based on a signal that is from the transmitting side and that carries the first to-be-decoded sequence. This is not limited in this disclosure.

3306: The receiving side performs CRC check on the first to-be-checked sequence.

3307: When the check on the first to-be-checked sequence succeeds, the receiving side performs deinterleaving on the second bit sequence by using a first distributed CRC deinterleaver, to obtain the K1 information bits.

When the check on the first to-be-checked sequence succeeds, the to-be-checked sequence is the second bit sequence. For step 3301 to step 3307, refer to step 401 to step 407 in FIG. 4. In a possible implementation, when the check on the first to-be-checked sequence fails, the decoding is terminated in advance.

3308: The transmitting side performs CRC encoding on K3 control bits based on the CRC generator polynomial, to obtain a fourth bit sequence.

K3 is an integer greater than 0.

3309: The transmitting side performs interleaving on the fourth bit sequence by using the first distributed CRC interleaver, to obtain a fifth bit sequence.

3310: The transmitting side performs polar encoding on the fifth bit sequence, to obtain a sixth bit sequence.

3311: The transmitting side sends a second to-be-decoded sequence obtained by performing a part or all of steps including but not limited to rate matching, modulation, analog-to-digital conversion, and frequency conversion on the sixth bit sequence.

Correspondingly, the receiving side receives, from the transmitting side, a signal that carries the second to-be-decoded sequence.

In step 3311, the obtained second to-be-decoded sequence sent by the transmitting side may be a sent control signal, that is, a control signal used by the receiving side to obtain the K3 control bits through decoding. Step 3308 to step 3311 include a process in which the transmitting side performs channel encoding on the K3 control bits that need to be sent through a control channel. For example, the second to-be-decoded sequence sent by the transmitting side is carried in an LP-WUS.

3312: The receiving side performs decoding on the second to-be-decoded sequence, to obtain a second to-be-checked sequence.

3313: The receiving side performs CRC check on the second to-be-checked sequence.

3314: When the check on the second to-be-checked sequence succeeds, the receiving side performs deinterleaving on the fifth bit sequence by using the first distributed CRC deinterleaver, to obtain the K3 control bits.

When the check on the second to-be-checked sequence succeeds, the to-be-checked sequence is the fifth bit sequence. For step 3308 to step 3314, refer to step 401 to step 407 in FIG. 4. A sequence of step 3301 to step 3307 and step 3308 to step 3314 is not limited. In a possible implementation, when the check on the second to-be-checked sequence fails, the decoding is terminated in advance.

In this embodiment of this disclosure, the control channel and the data channel share NR control channel encoding. In other words, the channel coding scheme provided in this disclosure is friendly to and compatible with the NR standard, which reduces encoding/decoding complexity.

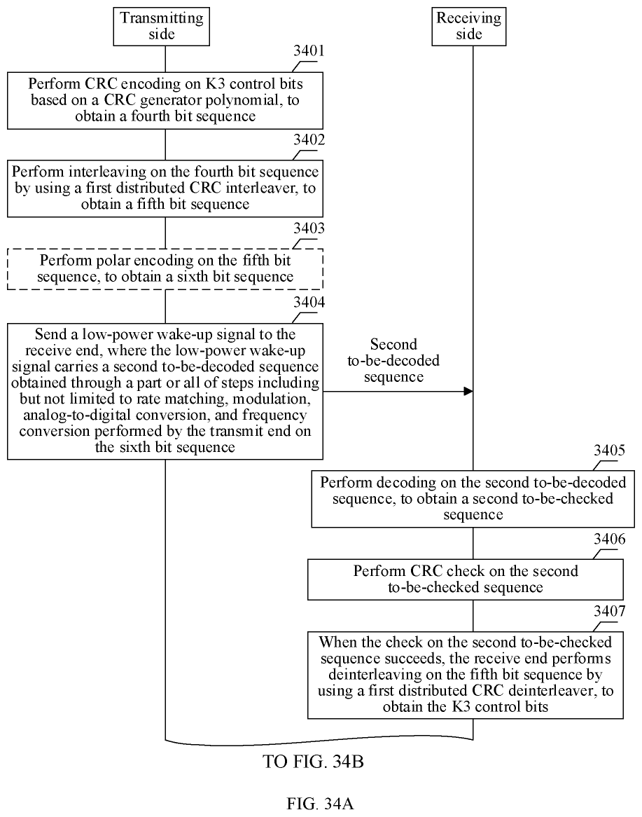

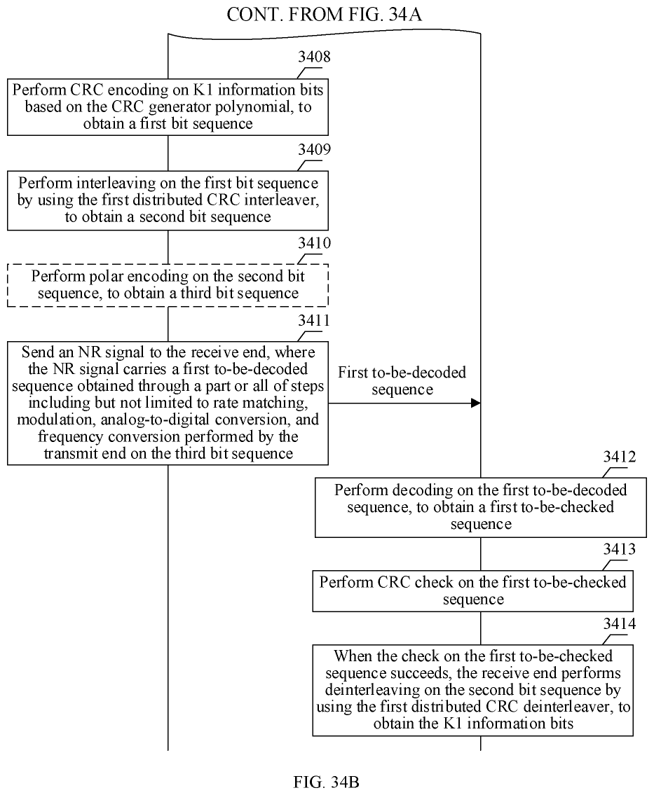

FIG. 34A and FIG. 34B each are a flowchart of another encoding method according to an embodiment of this disclosure. A method procedure in FIG. 34A and FIG. 34B is a possible implementation of the method described in FIG. 4. The method procedure in FIG. 34A and FIG. 34B may be applied to low-power scenarios. As shown in FIG. 34A and FIG. 34B, the method includes the following steps.

3401: A transmitting side performs CRC encoding on K3 control bits based on a CRC generator polynomial, to obtain a fourth bit sequence.

K3 is an integer greater than 0.

3402: The transmitting side performs interleaving on the fourth bit sequence by using a first distributed CRC interleaver, to obtain a fifth bit sequence.

3403: The transmitting side performs polar encoding on the fifth bit sequence, to obtain a sixth bit sequence.

3404: The transmitting side sends a low-power wake-up signal to a receiving side, where the low-power wake-up signal carries a second to-be-decoded sequence obtained through a part or all of steps including but not limited to rate matching, modulation, analog-to-digital conversion, and frequency conversion performed by the transmitting side on the sixth bit sequence.

Correspondingly, the receiving side receives the low-power wake-up signal from the transmitting side.

The low-power wake-up signal is used to wake up a main receiver of the receiving side. The receiving side may include the main receiver and the low-power wake-up receiver shown in FIG. 1.

3405: The receiving side performs decoding on the second to-be-decoded sequence, to obtain a second to-be-checked sequence.

3406: The receiving side performs CRC check on the second to-be-checked sequence.

3407: When the check on the second to-be-checked sequence succeeds, the receiving side performs deinterleaving on the fifth bit sequence by using a first distributed CRC deinterleaver, to obtain the K3 control bits.

For step 3401 to step 3407, refer to step 401 to step 407 in FIG. 4. In a possible implementation, when the check on the second to-be-checked sequence fails, the decoding is terminated in advance.

3408: The transmitting side performs CRC encoding on K1 information bits based on the CRC generator polynomial, to obtain a first bit sequence.

3409: The transmitting side performs interleaving on the first bit sequence by using the first distributed CRC interleaver, to obtain a second bit sequence.

3410: The transmitting side performs polar encoding on the second bit sequence, to obtain a third bit sequence.

3411: The transmitting side sends an NR signal to the receiving side, where the NR signal carries a first to-be-decoded sequence obtained through a part or all of steps including but not limited to rate matching, modulation, analog-to-digital conversion, and frequency conversion performed by the transmitting side on the third bit sequence.

Correspondingly, the receiving side receives the NR signal from the transmitting side.

In a possible implementation, in step 3411, the obtained first to-be-decoded sequence sent by the transmitting side may be a sent data signal, that is, a data signal used by the receiving side to obtain the K1 information bits through decoding. Step 3408 to step 3411 include a process in which the transmitting side performs channel encoding on the K1 information bits that need to be sent through a data channel.

In a possible implementation, in step 3411, the obtained first to-be-decoded sequence sent by the transmitting side may be a sent broadcast signal, that is, a broadcast signal used by the receiving side to obtain the K1 information bits through decoding. Step 3408 to step 3411 include a process in which the transmitting side performs channel encoding on the K1 information bits that need to be sent through a broadcast channel.

3412: The receiving side performs decoding on the first to-be-decoded sequence, to obtain a first to-be-checked sequence.

3413: The receiving side performs CRC check on the first to-be-checked sequence.

3414: When the check on the first to-be-checked sequence succeeds, the receiving side performs deinterleaving on the second bit sequence by using the first distributed CRC deinterleaver, to obtain the K1 information bits.

For step 3408 to step 3414, refer to step 401 to step 407 in FIG. 4. In a possible implementation, when the check on the first to-be-checked sequence fails, the decoding is terminated in advance.

In this embodiment of this disclosure, the low-power wake-up signal and the NR signal share NR control channel encoding. In other words, the channel coding scheme provided in this disclosure is friendly to and compatible with the NR standard, which reduces encoding/decoding complexity.

With reference to the accompanying drawings, the following describes a structure of a transmitting side that can implement an encoding method provided in embodiments of this disclosure, and a structure of a receiving side that can implement a decoding method provided in embodiments of this disclosure. In this disclosure, both the transmitting side and the receiving side may be communication apparatuses. The following briefly describes only that the transmitting side and the receiving side are communication apparatuses. For details about solution implementation, refer to the descriptions in the foregoing method embodiments. Details are not described below again.

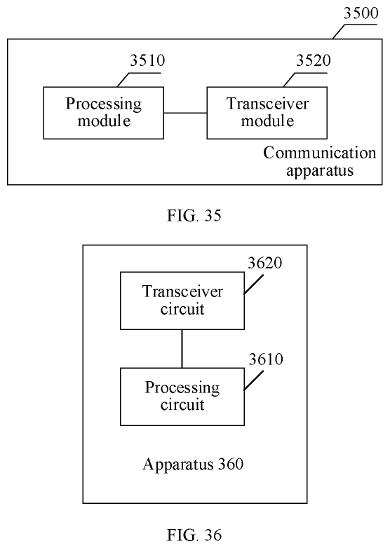

FIG. 35 is a diagram of a structure of a communication apparatus 3500 according to an embodiment of this disclosure. The communication apparatus 3500 may correspondingly implement functions or steps implemented by the transmitting side in the foregoing method embodiments, or may correspondingly implement functions or steps implemented by the receiving side in the foregoing method embodiments. The communication apparatus may include a processing module 3510 and a transceiver module 3520. In a possible implementation, the apparatus may further include a storage unit. The storage unit may be configured to store instructions (code or a program) and/or data. The processing module 3510 and the transceiver module 3520 may be coupled to the storage unit. For example, the processing module 3510 may read the instructions (the code or the program) and/or the data in the storage unit, to implement a corresponding method. The foregoing units may be independently disposed, or may be partially or completely integrated. For example, the transceiver module 3520 may include a sending module and a receiving module. The sending module may be a transmitter, and the receiving module may be a receiver. An entity corresponding to the transceiver module 3520 may be a transceiver circuit, for example, a transceiver or a communication interface.

In some possible implementations, the communication apparatus 3500 can correspondingly implement behavior and the functions of the transmitting side in the foregoing method embodiments. For example, the communication apparatus 3500 may be the transmitting side, or may be a component (for example, a chip or a circuit) used in the transmitting side. For example, the transceiver module 3520 may be configured to perform all receiving or sending operations performed by the transmitting side in the embodiment in FIG. 3, FIG. 4, FIG. 33A and FIG. 33B, or FIG. 34A and FIG. 34B. For example, the processing module 3510 may be configured to perform all operations other than the receiving or sending operations performed by the transmitting side in the embodiment in FIG. 3, FIG. 4, FIG. 33A and FIG. 33B, or FIG. 34A and FIG. 34B.

In some possible implementations, the communication apparatus 3500 can correspondingly implement behavior and the functions of the receiving side in the foregoing method embodiments. For example, the communication apparatus 3500 may be the receiving side, or may be a component (for example, a chip or a circuit) used in the receiving side. For example, the transceiver module 3520 may be configured to perform all receiving or sending operations performed by the receiving side in the embodiment in FIG. 3, FIG. 4, FIG. 33A and FIG. 33B, or FIG. 34A and FIG. 34B. For example, the processing module 3510 may be configured to perform all operations other than the receiving or sending operations performed by the receiving side in the embodiment in FIG. 3, FIG. 4, FIG. 33A and FIG. 33B, or FIG. 34A and FIG. 34B.

FIG. 36 is a diagram of a structure of another apparatus 360 according to an embodiment of this disclosure. The apparatus in FIG. 36 may be the transmitting side or a chip used in the transmitting side, or may be the receiving side or a chip used in the receiving side. As shown in FIG. 36, the apparatus 360 includes a processing circuit 3610 and a transceiver circuit 3620.

In some embodiments of this disclosure, the processing circuit 3610 and the transceiver circuit 3620 may be configured to perform a function, an operation, or the like performed by the transmitting side. For example, the transceiver circuit 3620 is configured to perform all receiving or sending operations performed by the transmitting side in the embodiment in FIG. 3, FIG. 4, FIG. 33A and FIG. 33B, or FIG. 34A and FIG. 34B. For example, the processing circuit 3610 is configured to perform all operations other than the receiving or sending operations performed by the transmitting side in the embodiment in FIG. 3, FIG. 4, FIG. 33A and FIG. 33B, or FIG. 34A and FIG. 34B.

In some embodiments of this disclosure, the processing circuit 3610 and the transceiver circuit 3620 may be configured to perform a function, an operation, or the like performed by the receiving side. For example, the transceiver circuit 3620 is configured to perform all receiving or sending operations performed by the receiving side in the embodiment in FIG. 3, FIG. 4, FIG. 33A and FIG. 33B, or FIG. 34A and FIG. 34B. For example, the processing circuit 3610 is configured to perform all operations other than the receiving or sending operations performed by the receiving side in the embodiment in FIG. 3, FIG. 4, FIG. 33A and FIG. 33B, or FIG. 34A and FIG. 34B.

In a possible implementation, the transceiver circuit 3620 includes at least one transceiver, and the processing circuit 3610 includes at least one processor or a circuit that is in the at least one processor and that is used for processing or control.

The transceiver is configured to communicate with another device/apparatus through a transmission medium. The processor sends and receives data and/or signaling through the transceiver, and is configured to implement the methods in the foregoing method embodiments. The processor may implement a function of the processing module 3510, and the transceiver may implement a function of the transceiver module 3520. Optionally, the transceiver may include a radio frequency circuit and an antenna. The radio frequency circuit is mainly configured to: perform conversion between a baseband signal and a radio frequency signal, and process the radio frequency signal. The antenna is mainly configured to receive and send a radio frequency signal in a form of an electromagnetic wave. An input/output apparatus, for example, a touchscreen, a display, or a keyboard, is mainly configured to: receive data input by a user and output data to the user.

Optionally, the apparatus 360 may further include at least one memory, configured to store program instructions and/or data. The memory is coupled to the processor. The coupling in this embodiment of this disclosure may be an indirect coupling or a communication connection between apparatuses, units, or modules in an electrical form, a mechanical form, or another form, and is used for information exchange between the apparatuses, the units, or the modules. The processor may perform an operation in collaboration with the memory. The processor may execute the program instructions stored in the memory. At least one of the at least one memory may be included in the processor.

The processor may read a software program in the memory, interpret and execute instructions of the software program, and process data of the software program. When data needs to be sent wirelessly, the processor performs baseband processing on the to-be-sent data, and then outputs a baseband signal to the radio frequency circuit. The radio frequency circuit performs radio frequency processing on the baseband signal, and then sends, through the antenna, a radio frequency signal in an electromagnetic wave form. When data is sent to the apparatus 360, the radio frequency circuit receives a radio frequency signal through the antenna, converts the radio frequency signal into a baseband signal, and outputs the baseband signal to the processor. The processor converts the baseband signal into data, and processes the data.

In another implementation, the radio frequency circuit and the antenna may be disposed independent of the processor that performs baseband processing. For example, in a distributed scenario, the radio frequency circuit and the antenna may be remotely disposed independent of the apparatus 360.

A specific connection medium between the transceiver, the processor, and the memory is not limited in embodiments of this disclosure.

In embodiments of this disclosure, the processor may be one of the following components: a general-purpose processor, a digital signal processor, an application-specific integrated circuit, a field programmable gate array or another programmable logic device, a discrete gate or a transistor logic device, a discrete hardware component, or all or a part of circuits used for processing functions in the foregoing components. The processor may implement or perform the methods, the steps, and the logical block diagrams disclosed in embodiments of this disclosure. The general-purpose processor may be a microprocessor, any processor, or the like. The steps of the methods disclosed with reference to embodiments of this disclosure may be directly performed and completed by a hardware processor, or may be performed and completed by using a combination of hardware in the processor and a software module.

In a possible implementation, the processing circuit 3610 includes at least one logic circuit, and the transceiver circuit 3620 includes at least one interface. The processing module 3510 in FIG. 35 may be implemented by using the logic circuit, and the transceiver module 3520 in FIG. 35 may be implemented through the interface. The logic circuit may be a chip, a processing circuit, an integrated circuit, a system-on-chip (SoC), or the like. The interface may be a communication interface, an input/output interface, or the like. In this embodiment of this disclosure, the logic circuit and the interface may alternatively be coupled to each other. A specific manner of connection between the logic circuit and the interface is not limited in this embodiment of this disclosure.

This disclosure further provides a computer-readable storage medium. The computer-readable storage medium stores a computer program or instructions. When the computer program or the instructions are run on a computer, the computer is enabled to perform the methods in the foregoing embodiments.

This disclosure further provides a computer program product. The computer program product includes instructions or a computer program. When the instructions or the computer program is run on a computer, the methods in the foregoing embodiments are performed.

This disclosure further provides a communication system, including the transmitting side and the receiving side.

This disclosure further provides a chip. The chip includes a communication interface and a processor. The communication interface is configured to receive and send a signal of the chip. The processor is configured to execute computer program instructions, to enable a communication apparatus including the chip to perform the method in the foregoing embodiments.

All or a part of the foregoing embodiments may be implemented by using software, hardware, firmware, or any combination thereof. When the software is used to implement embodiments, all or a part of embodiments may be implemented in a form of a computer program product. The computer program product includes one or more computer programs or instructions. When the computer programs or instructions are loaded and executed on a computer, all or a part of procedures or functions in embodiments of this disclosure are performed. The computer may be a general-purpose computer, a dedicated computer, a computer network, a network device, user equipment, or another programmable apparatus. The computer programs or instructions may be stored in a computer-readable storage medium, or may be transmitted from a computer-readable storage medium to another computer-readable storage medium. For example, the computer programs or instructions may be transmitted from a website, computer, server, or data center to another website, computer, server, or data center in a wired or wireless manner. The computer-readable storage medium may be any usable medium that can be accessed by the computer, or a data storage device, for example, a server or a data center, integrating one or more usable media. The usable medium may be a magnetic medium, for example, a floppy disk, a hard disk drive, or a magnetic tape; may be an optical medium, for example, a digital video disc; or may be a semiconductor medium, for example, a solid-state drive. The computer-readable storage medium may be a volatile or non-volatile storage medium, or may include two types of storage media: a volatile storage medium and a non-volatile storage medium.

In embodiments of this disclosure, unless otherwise stated or there is a logic conflict, terms and/or descriptions in different embodiments are consistent and may be mutually referenced, and technical features in different embodiments may be combined based on an internal logical relationship thereof, to form a new embodiment.

1. An encoding method, comprising:
performing cyclic redundancy check (CRC) encoding on K1 information bits to obtain a first bit sequence, wherein the first bit sequence comprises the K1 information bits and L CRC bits, wherein K1 is a positive integer, and wherein L is a positive integer less than 24; and
performing interleaving on the first bit sequence by using a first distributed CRC interleaver, to obtain a second bit sequence,
wherein the first distributed CRC interleaver comprises (K2+L) elements, values of a (K2+L−S)^{th} element to a (K2+L)^{th} element in the first distributed CRC interleaver are sequentially (K2+L−1−S) to (K2+L−1), S is an integer greater than or equal to 0 and less than or equal to L, and K2 is an integer greater than or equal to K1, or
wherein the first distributed CRC interleaver comprises (K2+L) elements, the (K2+L) elements are natural numbers ranging from 0 to (K2+L−1), P in the first distributed CRC interleaver is before Q, both P and Q are integers greater than or equal to K2, and P is greater than Q.

2. The encoding method of claim 1, wherein Lis equal to 6, 11, or 16.

3. The encoding method of claim 2, wherein K2 is equal to 32, 40, 48, 54, 64, 70, or 100.

4. The encoding method of claim 1, further comprising:
obtaining the first distributed CRC interleaver by sequentially arranging L element sequences, wherein any two of the L element sequences are a first element sequence and a second element sequence, wherein each element of the first element sequence identifies a first position of a first information bit associated with a first check column, wherein each element of the second element sequence identifies a second position of a second information bit associated with a second check column, and wherein the first check column and the second check column are any two columns in a check matrix that is based on an L-length CRC generator polynomial; and
arranging the first element sequence after the second element sequence in the first distributed CRC interleaver when a first largest element in the first element sequence exceeds a second largest element in the second element sequence.

5. The encoding method of claim 1, wherein performing the CRC encoding comprises performing, based on a CRC generator polynomial, the CRC encoding to obtain the first bit sequence, wherein L is equal to 6, wherein K2 is equal to 70, wherein the CRC generator polynomial is D\hat{ }6+D\hat{ }5+1, and wherein values of the (K2+L) elements are sequentially as follows: 0, 2, 3, 4, 5, 6, 7, 13, 18, 19, 23, 25, 28, 29, 30, 31, 33, 37, 38, 39, 42, 45, 47, 48, 50, 51, 52, 54, 55, 58, 59, 61, 63, 65, 66, 67, 68, 69, 70, 1, 8, 14, 20, 24, 26, 32, 34, 40, 43, 46, 49, 53, 56, 60, 62, 64, 71, 9, 15, 21, 27, 35, 41, 44, 57, 72, 10, 16, 22, 36, 73, 11, 17, 74, 12, and 75.

6. The encoding method of claim 1, wherein performing the CRC encoding comprises performing, based on a CRC generator polynomial, the CRC encoding to obtain the first bit sequence, wherein L is equal to 6, wherein K2 is equal to 70, wherein the CRC generator polynomial is D\hat{ }6+D\hat{ }5+D\hat{ }4+D\hat{ }3+1, and wherein values of the (K2+L) elements are sequentially as follows: 1, 4, 5, 6, 9, 10, 16, 19, 20, 21, 24, 25, 31, 34, 35, 36, 39, 40, 46, 49, 50, 51, 54, 55, 61, 64, 65, 66, 69, 70, 2, 7, 11, 17, 22, 26, 32, 37, 41, 47, 52, 56, 62, 67, 71, 3, 8, 12, 18, 23, 27, 33, 38, 42, 48, 53, 57, 63, 68, 72, 13, 28, 43, 58, 73, 14, 29, 44, 59, 74, 0, 15, 30, 45, 60, and 75.

7. The encoding method of claim 1, wherein performing the CRC encoding comprises performing, based on a CRC generator polynomial, the CRC encoding to obtain the first bit sequence, wherein L is equal to 6, wherein K2 is equal to 70, wherein the CRC generator polynomial is D\hat{ }6+D\hat{ }4+D\hat{ }3+D+1, and wherein values of the (K2+L) elements are sequentially as follows: 0, 1, 2, 3, 4, 5, 7, 13, 14, 15, 20, 23, 27, 28, 30, 31, 34, 36, 37, 39, 41, 42, 43, 45, 46, 47, 48, 51, 52, 56, 58, 60, 63, 64, 65, 66, 67, 68, 70, 6, 8, 16, 21, 24, 29, 32, 35, 38, 40, 44, 49, 53, 57, 59, 61, 69, 71, 9, 17, 22, 25, 33, 50, 54, 62, 72, 10, 18, 26, 55, 73, 11, 19, 74, 12, and 75.

8. The encoding method of claim 1, wherein performing the CRC encoding comprises performing, based on a CRC generator polynomial, the CRC encoding to obtain the first bit sequence, wherein L is equal to 6, wherein K2 is equal to 70, wherein the CRC generator polynomial is D\hat{ }6+D\hat{ }3+D\hat{ }2+D+1, and wherein values of the (K2+L) elements are sequentially as follows: 1, 2, 5, 6, 7, 10, 16, 17, 20, 21, 22, 25, 31, 32, 35, 36, 37, 40, 46, 47, 50, 51, 52, 55, 61, 62, 65, 66, 67, 70, 3, 8, 11, 18, 23, 26, 33, 38, 41, 48, 53, 56, 63, 68, 71, 4, 9, 12, 19, 24, 27, 34, 39, 42, 49, 54, 57, 64, 69, 72, 13, 28, 43, 58, 73, 14, 29, 44, 59, 74, 0, 15, 30, 45, 60, and 75.

9. The encoding method of claim 1, wherein performing the CRC encoding comprises performing, based on a CRC generator polynomial, the CRC encoding to obtain the first bit sequence, wherein L is equal to 6, wherein K2 is equal to 70, wherein the CRC generator polynomial is D\hat{ }6+D\hat{ }5+D\hat{ }2+1, and wherein values of the (K2+L) elements are sequentially as follows: 0, 1, 2, 4, 5, 6, 7, 13, 15, 17, 18, 21, 22, 23, 25, 26, 27, 28, 34, 36, 38, 39, 42, 43, 44, 46, 47, 48, 49, 55, 57, 59, 60, 63, 64, 65, 67, 68, 69, 70, 3, 8, 14, 16, 19, 24, 29, 35, 37, 40, 45, 50, 56, 58, 61, 66, 71, 9, 20, 30, 41, 51, 62, 72, 10, 31, 52, 73, 11, 32, 53, 74, 12, 33, 54, and 75.

10. The encoding method of claim 1, wherein performing the CRC encoding comprises performing, based on a CRC generator polynomial, the CRC encoding to obtain the first bit sequence, wherein L is equal to 6, wherein K2 is equal to 70, wherein the CRC generator polynomial is D\hat{ }6+D\hat{ }5+D\hat{ }4+D\hat{ }2+1, and wherein values of the (K2+L) elements are sequentially as follows: 0, 1, 4, 6, 7, 13, 15, 18, 21, 22, 25, 27, 28, 34, 36, 39, 42, 43, 46, 48, 49, 55, 57, 60, 63, 64, 67, 69, 70, 2, 5, 8, 14, 16, 19, 23, 26, 29, 35, 37, 40, 44, 47, 50, 56, 58, 61, 65, 68, 71, 3, 9, 17, 20, 24, 30, 38, 41, 45, 51, 59, 62, 66, 72, 10, 31, 52, 73, 11, 32, 53, 74, 12, 33, 54, and 75.

11. The encoding method of claim 1, wherein performing the CRC encoding comprises performing, based on a CRC generator polynomial, the CRC encoding to obtain the first bit sequence, wherein L is equal to 6, wherein K2 is equal to 70, wherein the CRC generator polynomial is D\hat{ }6+D\hat{ }3+D\hat{ }2+1, and wherein values of the (K2+L) elements are sequentially as follows: 0, 4, 5, 8, 14, 16, 17, 18, 20, 21, 23, 25, 28, 29, 30, 31, 35, 36, 39, 45, 47, 48, 49, 51, 52, 54, 56, 59, 60, 61, 62, 66, 67, 70, 1, 6, 9, 15, 19, 22, 24, 26, 32, 37, 40, 46, 50, 53, 55, 57, 63, 68, 71, 2, 7, 10, 27, 33, 38, 41, 58, 64, 69, 72, 3, 11, 34, 42, 65, 73, 12, 43, 74, 13, 44, and 75.

12. The encoding method of claim 1, wherein performing the CRC encoding comprises performing, based on a CRC generator polynomial, the CRC encoding to obtain the first bit sequence, wherein L is equal to 6, wherein K2 is equal to 70, wherein the CRC generator polynomial is D\hat{ }6+D\hat{ }5+D\hat{ }3+D\hat{ }2+1, and wherein values of the (K2+L) elements are sequentially as follows: 0, 5, 6, 7, 13, 15, 16, 17, 18, 19, 20, 23, 25, 27, 31, 32, 35, 36, 37, 38, 40, 41, 42, 44, 46, 47, 49, 52, 53, 55, 56, 60, 63, 68, 69, 70, 1, 8, 14, 21, 24, 26, 28, 33, 39, 43, 45, 48, 50, 54, 57, 61, 64, 71, 2, 9, 22, 29, 34, 51, 58, 62, 65, 72, 3, 10, 30, 59, 66, 73, 4, 11, 67, 74, 12, and 75.

13. The encoding method of claim 1, wherein performing the CRC encoding comprises performing, based on a CRC generator polynomial, the CRC encoding to obtain the first bit sequence, wherein L is equal to 6, wherein K2 is equal to 70, wherein the CRC generator polynomial is D\hat{ }6+D\hat{ }5+D\hat{ }4+D\hat{ }3+D\hat{ }2+1, and wherein values of the (K2+L) elements are sequentially as follows: 0, 2, 5, 9, 10, 16, 18, 19, 21, 22, 23, 26, 27, 28, 29, 30, 32, 35, 39, 40, 46, 48, 49, 51, 52, 53, 56, 57, 58, 59, 60, 62, 65, 69, 70, 1, 3, 6, 11, 17, 20, 24, 31, 33, 36, 41, 47, 50, 54, 61, 63, 66, 71, 4, 7, 12, 25, 34, 37, 42, 55, 64, 67, 72, 8, 13, 38, 43, 68, 73, 14, 44, 74, 15, 45, and 75.

14. The encoding method of claim 1, wherein performing the CRC encoding comprises performing, based on a CRC generator polynomial, the CRC encoding to obtain the first bit sequence, wherein L is equal to 6, wherein K2 is equal to 70, wherein the CRC generator polynomial is D\hat{ }6+D\hat{ }5+D\hat{ }4+D\hat{ }3+D+1, and wherein values of the (K2+L) elements are sequentially as follows: 1, 2, 4, 7, 8, 14, 15, 16, 19, 23, 25, 27, 28, 29, 30, 32, 33, 35, 38, 39, 45, 46, 47, 50, 54, 56, 58, 59, 60, 61, 63, 64, 66, 69, 70, 0, 3, 5, 9, 17, 20, 24, 26, 31, 34, 36, 40, 48, 51, 55, 57, 62, 65, 67, 71, 6, 10, 18, 21, 37, 41, 49, 52, 68, 72, 11, 22, 42, 53, 73, 12, 43, 74, 13, 44, and 75.

15. The encoding method of claim 1, wherein performing the CRC encoding comprises performing, based on a CRC generator polynomial, the CRC encoding to obtain the first bit sequence, wherein L is equal to 6, wherein K2 is equal to 70, wherein the CRC generator polynomial is D\hat{ }6+D\hat{ }4+D\hat{ }2+D+1, and wherein values of the (K2+L) elements are sequentially as follows: 2, 5, 7, 13, 14, 16, 19, 20, 23, 26, 28, 34, 35, 37, 40, 41, 44, 47, 49, 55, 56, 58, 61, 62, 65, 68, 70, 0, 3, 6, 8, 15, 17, 21, 24, 27, 29, 36, 38, 42, 45, 48, 50, 57, 59, 63, 66, 69, 71, 1, 4, 9, 18, 22, 25, 30, 39, 43, 46, 51, 60, 64, 67, 72, 10, 31, 52, 73, 11, 32, 53, 74, 12, 33, 54, and 75.

16. The encoding method of claim 1, wherein performing the CRC encoding comprises performing, based on a CRC generator polynomial, the CRC encoding to obtain the first bit sequence, wherein L is equal to 11, wherein K2 is equal to 70, wherein the CRC generator polynomial is D\hat{ }11+D\hat{ }10+D\hat{ }9+D\hat{ }5+1, and wherein values of the (K2+L) elements are sequentially as follows: 0, 1, 2, 3, 4, 6, 7, 10, 13, 15, 19, 21, 22, 23, 24, 25, 27, 30, 33, 34, 35, 37, 41, 44, 46, 47, 48, 49, 50, 55, 57, 58, 59, 60, 61, 62, 63, 66, 67, 69, 70, 5, 8, 11, 14, 16, 20, 26, 28, 31, 36, 38, 42, 45, 51, 56, 64, 68, 71, 9, 12, 17, 29, 32, 39, 43, 52, 65, 72, 18, 40, 53, 73, 54, 74, 75, 76, 77, 78, 79, and 80.

17. The encoding method of claim 1, wherein performing the CRC encoding comprises performing, based on a CRC generator polynomial, the CRC encoding to obtain the first bit sequence, wherein L is equal to 11, wherein K2 is equal to 70, wherein the CRC generator polynomial is D\hat{ }11+D\hat{ }7+D\hat{ }6+D\hat{ }2+1, and wherein_values of the (K2+L) elements are sequentially as follows: 1, 5, 11, 13, 15, 16, 19, 20, 23, 24, 29, 30, 31, 32, 33, 35, 37, 39, 41, 43, 47, 52, 53, 54, 55, 56, 57, 58, 59, 60, 61, 62, 65, 66, 70, 2, 6, 12, 14, 17, 21, 25, 34, 36, 38, 40, 42, 44, 48, 63, 67, 71, 3, 7, 18, 22, 26, 45, 49, 64, 68, 72, 0, 4, 8, 27, 46, 50, 69, 73, 9, 28, 51, 74, 10, 75, 76, 77, 78, 79, and 80.

18. The encoding method of claim 1, wherein performing the CRC encoding comprises performing, based on a CRC generator polynomial, the CRC encoding to obtain the first bit sequence, wherein L is equal to 11, wherein K2 is equal to 70, wherein the CRC generator polynomial is D\hat{ }11+D\hat{ }10+D\hat{ }9+D\hat{ }6+D\hat{ }4+D\hat{ }2+1, and wherein_values of the (K2+L) elements are sequentially as follows: 0, 1, 5, 6, 9, 10, 12, 13, 14, 16, 19, 21, 22, 23, 24, 25, 26, 29, 34, 36, 37, 38, 41, 43, 47, 49, 50, 51, 52, 54, 61, 63, 64, 65, 66, 67, 69, 70, 2, 7, 11, 15, 17, 20, 27, 30, 35, 39, 42, 44, 48, 53, 55, 62, 68, 71, 3, 8, 18, 28, 31, 40, 45, 56, 72, 4, 32, 46, 57, 73, 33, 58, 74, 59, 75, 60, 76, 77, 78, 79, and 80.

19.-20. (canceled)

21. An apparatus, comprising:
a memory configured to store instructions; and
one or more processors coupled to the memory and configured to execute the instructions to cause the apparatus to:
perform cyclic redundancy check (CRC) encoding on K1 information bits to obtain a first bit sequence, wherein the first bit sequence comprises the K1 information bits and L CRC bits, wherein K1 is a positive integer, and wherein L is a positive integer less than 24; and
perform interleaving on the first bit sequence by using a first distributed CRC interleaver to obtain a second bit sequence,
wherein the first distributed CRC interleaver comprises (K2+L) elements, values of a (K2+L−S)^{th} element to a (K2+L)^{th} element in the first distributed CRC interleaver are sequentially (K2+L−1−S) to (K2+L−1), S is an integer greater than or equal to 0 and less than or equal to L, and K2 is an integer greater than or equal to K1, or
wherein the first distributed CRC interleaver comprises a total of (K2+L) natural numbers ranging from 0 to (K2+L−1), P in the first distributed CRC interleaver is before Q, both P and Q are integers greater than or equal to K2, and P is greater than Q.

22. A computer program product comprising instructions that are stored on a non-transitory computer-readable storage medium and that, when executed by one or more processors, cause an apparatus to:
perform cyclic redundancy check (CRC) encoding on K1 information bits to obtain a first bit sequence, wherein the first bit sequence comprises the K1 information bits and L CRC bits, wherein K1 is a positive integer, and wherein L is a positive integer less than 24; and
perform interleaving on the first bit sequence by using a first distributed CRC interleaver to obtain a second bit sequence,
wherein the first distributed CRC interleaver comprises (K2+L) elements, values of a (K2+L−S)^{th} element to a (K2+L)^{th} element in the first distributed CRC interleaver are sequentially (K2+L−1−S) to (K2+L−1), S is an integer greater than or equal to 0 and less than or equal to L, and K2 is an integer greater than or equal to K1, or
wherein the first distributed CRC interleaver comprises a total of (K2+L) natural numbers ranging from 0 to (K2+L−1), P in the first distributed CRC interleaver is before Q, both P and Q are integers greater than or equal to K2, and P is greater than Q.
